(19) United States
(12) Patent Application Publication
(10) Pub. No.: US 2025/0311413 A1
(43) Pub. Date: Oct. 2, 2025

(54) FINFET DEVICE AND METHOD

(71) Applicant: Taiwan Semiconductor Manufacturing Co., Ltd., Hsinchu (TW)

(72) Inventors: Tsai-Jung Ho, Xihu Township (TW); Tze-Liang Lee, Hsinchu (TW)

(21) Appl. No.: 19/233,336

(22) Filed: Jun. 10, 2025

Related U.S. Application Data
(63) Continuation of application No. 18/363,554, filed on Aug. 1, 2023.
Application No. 18/363,554 is a division of application No. 17/150,044, filed on Jan. 15, 2021.

(51) Int. Cl. H10D 84/85; H01L 21/02; H10D 30/01; H10D 30/62; H10D 62/10; H10D 64/01; H10D 84/01; H10D 84/03

(52) U.S. Cl. CPC H10D 84/853; H01L 21/0217; H01L 21/0228; H10D 30/024; H10D 30/62; H10D 62/116; H10D 64/021; H10D 84/013; H10D 84/0147; H10D 84/0158; H10D 84/038

(57) ABSTRACT

A device includes a fin extending from a semiconductor substrate; a gate stack over the fin; a spacer on a sidewall of the gate stack; a source/drain region in the fin adjacent the spacer; an inter-layer dielectric layer (ILD) extending over the gate stack, the spacer, and the source/drain region; a contact plug extending through the ILD and contacting the source/drain region; a dielectric layer including a first portion on a top surface of the ILD and a second portion extending between the ILD and the contact plug, wherein a top surface of the second portion is closer to the substrate than the top surface of the ILD; and an air gap between the spacer and the contact plug, wherein the second portion of the dielectric layer seals the top of the air gap.

### PRIORITY CLAIM AND CROSS-REFERENCE

This application is a continuation of U.S. patent application Ser. No. 18/363,554, filed on Aug. 1, 2023, which is a divisional of U.S. patent application Ser. No. 17/150,044, filed on Jan. 15, 2021, each application is hereby incorporated herein by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a FinFET in a three-dimensional view, in accordance with some embodiments.

FIGS. 2, 3, 4, 5, 6, 7, 8A, 8B, 9A, 9B, 10A, 10B, 10C, 10D, 11A, 11B, 12A, 12B, 13A, 13B, 14A, 14B, 14C, 15A, and 15B are cross-sectional views of intermediate stages in the manufacturing of FinFETs, in accordance with some embodiments.

FIGS. 16, 17, 18, 19, 20, 21, 22, 23A, 23B, 24A, 24B, 25A, 25B, 26A, 26B, 27A, 27B, and 28 are cross-sectional views of intermediate stages in the manufacturing of FinFETs having air gaps, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, air gaps are formed surrounding contacts to the source/drain epitaxial regions of a FinFET device. The low dielectric constant (k-value) of the air gaps can reduce capacitance between the gate stack and the contacts of the FinFET device, which can improve higher speed (e.g., “AC”) operation of the FinFET. In some embodiments, the deposition process of an overlying etch stop layer is controlled such that portions of the etch stop layer extend into the air gaps and seal upper regions of the air gaps. For example, the use of lower precursor doses during an ALD process can cause the material of the etch stop layer to grow in upper regions of the air gaps and seal the lower regions of the air gaps. The distance that the etch stop layer extends into the air gaps may be controlled by controlling the dose, in some embodiments. By sealing the air gaps, the chance of subsequently deposited conductive material entering the air gaps is reduced or eliminated. Accordingly, the chance of leakage or electrical shorts due to the presence of conductive material within the air gaps is reduced or eliminated.

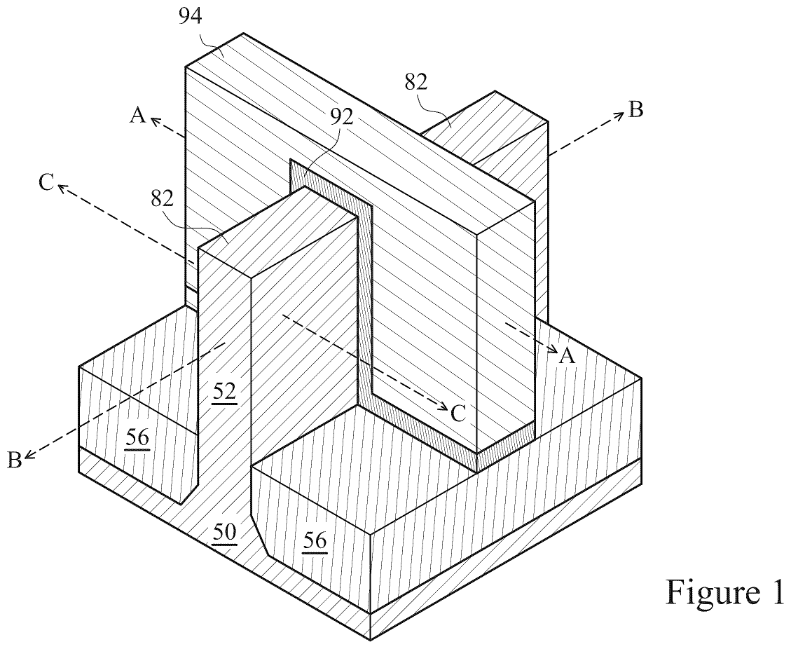

FIG. 1 illustrates an example of a FinFET in a three-dimensional view, in accordance with some embodiments. The FinFET comprises a fin 52 on a substrate 50 (e.g., a semiconductor substrate). Isolation regions 56 are disposed in the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a combination of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and gate electrode 94. FIG. 1 further illustrates reference cross-sections that are used in later figures. Cross-section A-A is along a longitudinal axis of the gate electrode 94 and in a direction, for example, perpendicular to the direction of current flow between the source/drain regions 82 of the FinFET. Cross-section B-B is perpendicular to cross-section A-A and is along a longitudinal axis of the fin 52 and in a direction of, for example, a current flow between the source/drain regions 82 of the FinFET. Cross-section C-C is parallel to cross-section A-A and extends through a source/drain region of the FinFET. Subsequent figures refer to these reference cross-sections for clarity.

Some embodiments discussed herein are discussed in the context of FinFETs formed using a gate-last process. In other embodiments, a gate-first process may be used. Also, some embodiments contemplate aspects used in planar devices, such as planar FETs.

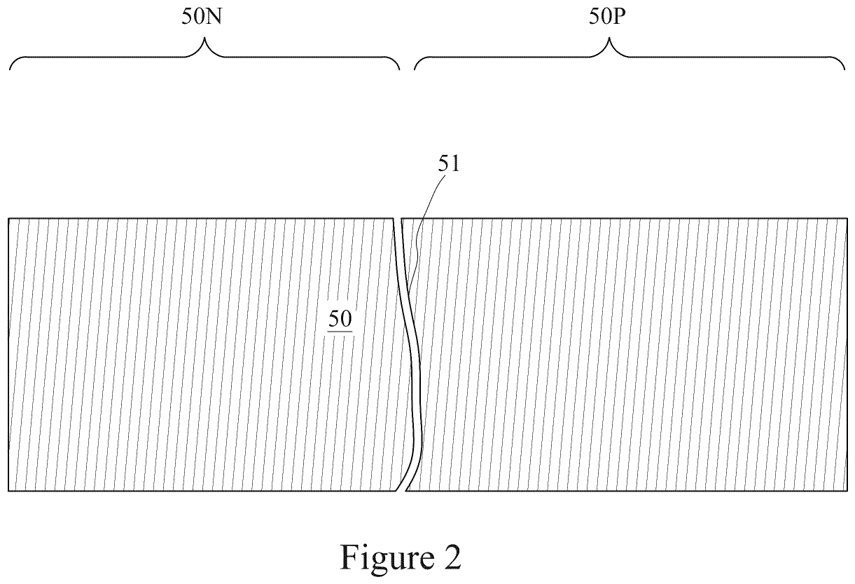

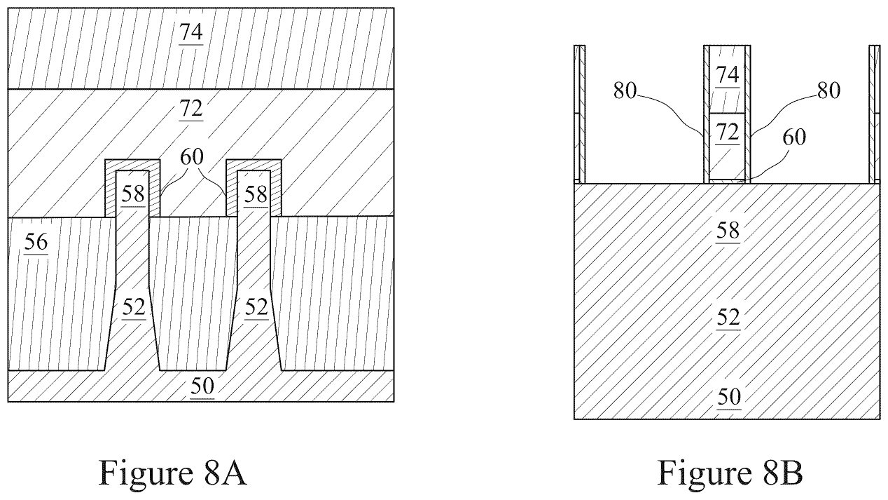

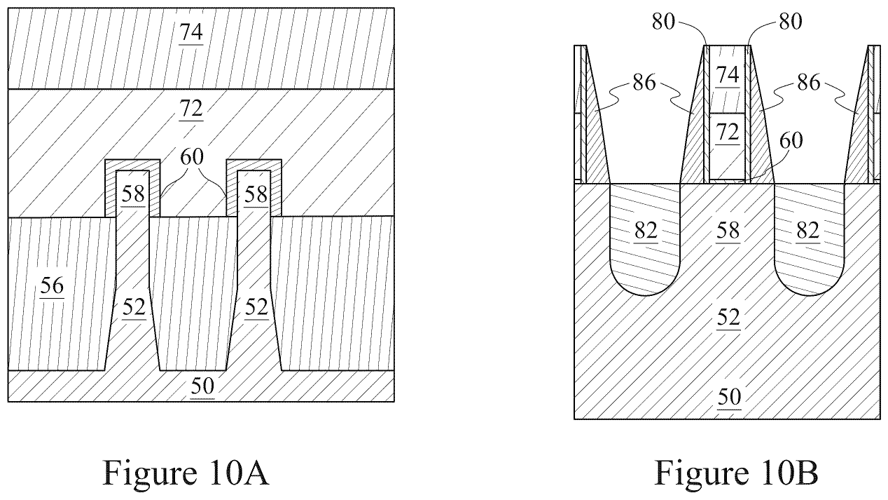

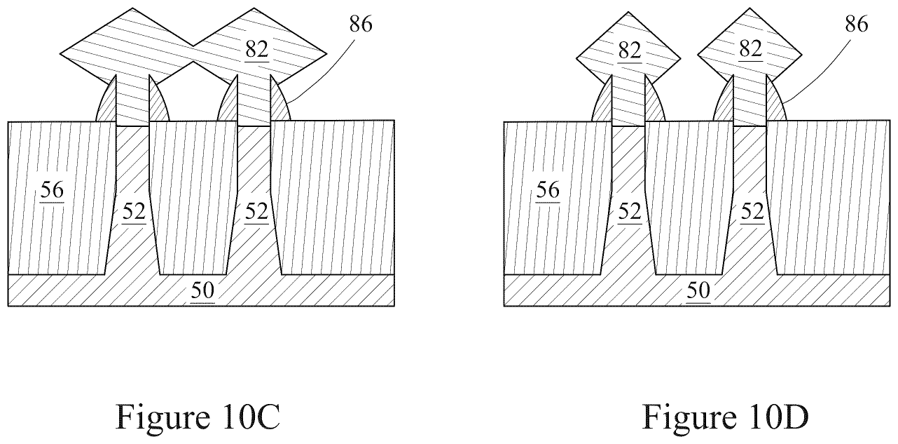

FIGS. 2 through 28 include cross-sectional views of intermediate stages in the manufacturing of FinFETs, in accordance with some embodiments. FIGS. 2 through 7 illustrate reference cross-section A-A illustrated in FIG. 1, except for multiple fins/FinFETs. FIGS. 8A, 9A, 10A, 11A, 12A, 13A, 14A, 15A, 24A, 25A, 26A, and 27A are illustrated along reference cross-section A-A illustrated in FIG. 1, and FIGS. 8B, 9B, 10B, 11B, 12B, 13B, 14B, 14C, 15B, 16, 17, 18, 19, 20, 21, 22, 23A, 23B, 24B, 25B, 26B, 27B, and 28 are illustrated along a similar cross-section B-B illustrated in FIG. 1, except for multiple fins/FinFETs. FIGS. 10C and 10D are illustrated along reference cross-section C-C illustrated in FIG. 1, except for multiple fins/FinFETs.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has a region 50N and a region 50P. The region 50N can be for forming n-type devices, such as NMOS transistors, e.g., n-type FinFETs. The region 50P can be for forming p-type devices, such as PMOS transistors, e.g., p-type FinFETs. The region 50N may be physically separated from the region 50P (as illustrated by divider 51), and any number of device features (e.g., other active devices, doped regions, isolation structures, etc.) may be disposed between the region 50N and the region 50P.

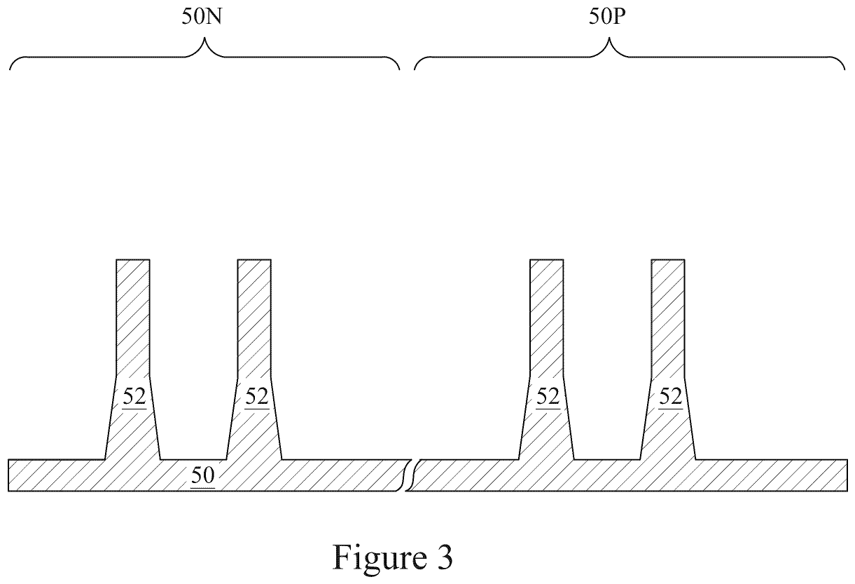

In FIG. 3, fins 52 are formed in the substrate 50. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. In some embodiments, the mask (or other layer) may remain on the fins 52.

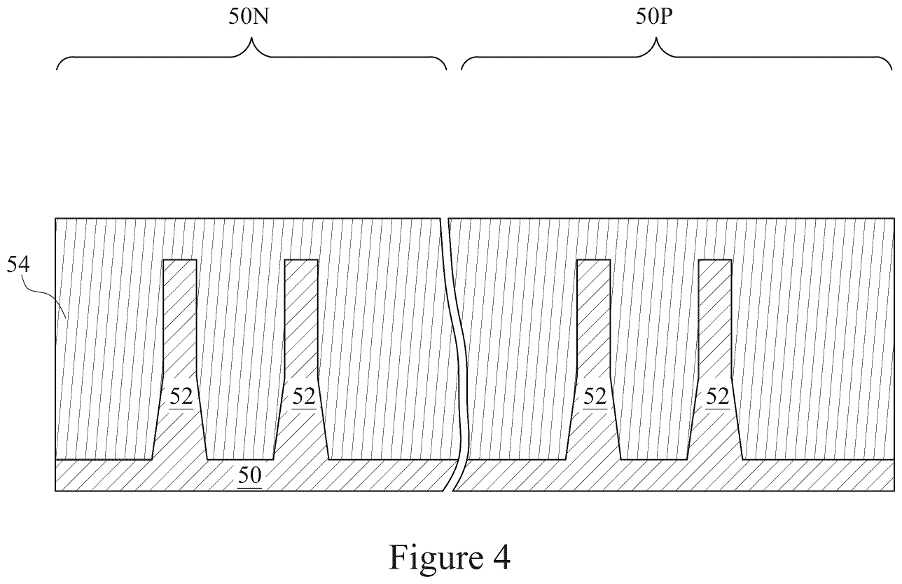

In FIG. 4, an insulation material 54 is formed over the substrate 50 and between neighboring fins 52. The insulation material 54 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments a liner (not shown) may first be formed along a surface of the substrate 50 and the fins 52. Thereafter, a fill material, such as those discussed above may be formed over the liner.

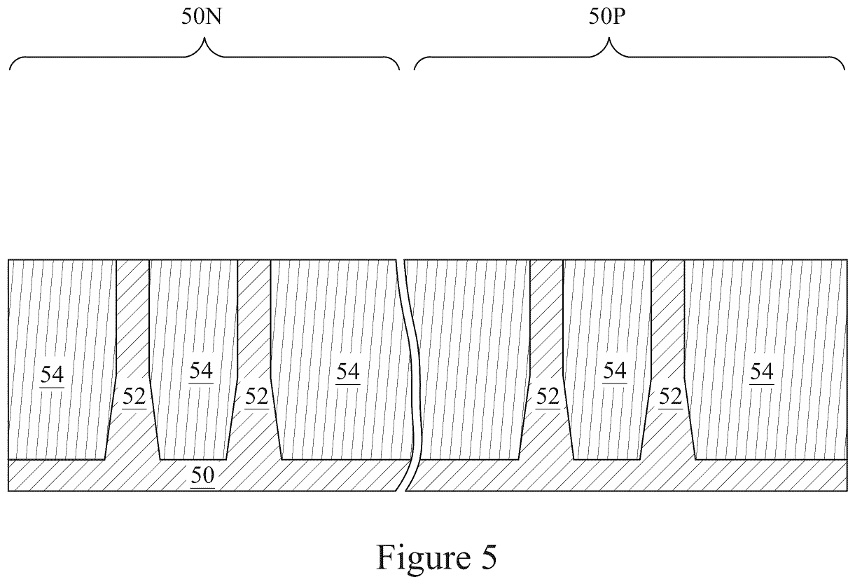

In FIG. 5, a removal process is applied to the insulation material 54 to remove excess insulation material 54 over the fins 52. In some embodiments, a planarization process such as a chemical mechanical polish (CMP), an etch-back process, combinations thereof, or the like may be utilized. The planarization process exposes the fins 52 such that top surfaces of the fins 52 and the insulation material 54 are level after the planarization process is complete. In embodiments in which a mask remains on the fins 52, the planarization process may expose the mask or remove the mask such that top surfaces of the mask or the fins 52, respectively, and the insulation material 54 are level after the planarization process is complete.

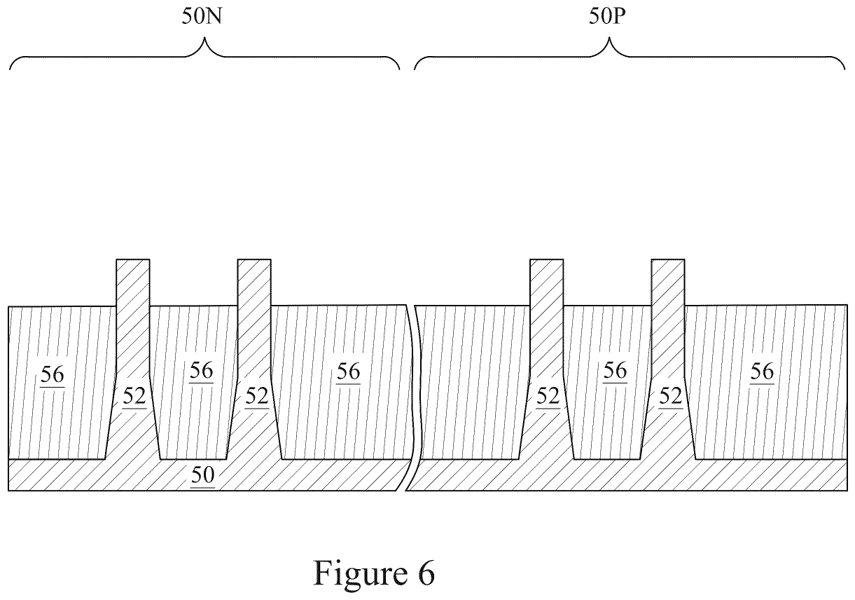

In FIG. 6, the insulation material 54 is recessed to form Shallow Trench Isolation (STI) regions 56. The insulation material 54 is recessed such that upper portions of fins 52 in the region 50N and in the region 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54 (e.g., etches the material of the insulation material 54 at a faster rate than the material of the fins 52). For example, an oxide removal using, for example, dilute hydrofluoric (dHF) acid may be used.

The process described with respect to FIGS. 2 through 6 is just one example of how the fins 52 may be formed. In some embodiments, the fins may be formed by an epitaxial growth process. For example, a dielectric layer can be formed over a top surface of the substrate 50, and trenches can be etched through the dielectric layer to expose the underlying substrate 50. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins 52. For example, the fins 52 in FIG. 5 can be recessed, and a material different from the fins 52 may be epitaxially grown over the recessed fins 52. In such embodiments, the fins 52 comprise the recessed material as well as the epitaxially grown material disposed over the recessed material. In an even further embodiment, a dielectric layer can be formed over a top surface of the substrate 50, and trenches can be etched through the dielectric layer. Heteroepitaxial structures can then be epitaxially grown in the trenches using a material different from the substrate 50, and the dielectric layer can be recessed such that the heteroepitaxial structures protrude from the dielectric layer to form the fins 52. In some embodiments where homoepitaxial or heteroepitaxial structures are epitaxially grown, the epitaxially grown materials may be in situ doped during growth, which may obviate prior and subsequent implantations although in situ and implantation doping may be used together.

Still further, it may be advantageous to epitaxially grow a material in region 50N (e.g., an NMOS region) different from the material in region 50P (e.g., a PMOS region). In various embodiments, upper portions of the fins 52 may be formed from silicon-germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, indium arsenide, aluminum arsenide, gallium arsenide, indium phosphide, gallium nitride, indium gallium arsenide, indium aluminum arsenide, gallium antimonide, aluminum antimonide, aluminum phosphide, gallium phosphide, and the like.

Further in FIG. 6, appropriate wells (not shown) may be formed in the fins 52 and/or the substrate 50. In some embodiments, a P well may be formed in the region 50N, and an N well may be formed in the region 50P. In some embodiments, a P well or an N well are formed in both the region 50N and the region 50P.

In the embodiments with different well types, the different implant steps for the region 50N and the region 50P may be achieved using a photoresist or other masks (not shown). For example, a photoresist may be formed over the fins 52 and the STI regions 56 in the region 50N. The photoresist is patterned to expose the region 50P of the substrate 50, such as a PMOS region. The photoresist can be formed by using a spin-on technique and can be patterned using acceptable photolithography techniques. Once the photoresist is patterned, an n-type impurity implant is performed in the region 50P, and the photoresist may act as a mask to substantially prevent n-type impurities from being implanted into the region 50N, such as an NMOS region. The n-type impurities may be phosphorus, arsenic, antimony, or the like implanted in the region to a concentration of equal to or less than 10¹⁸ cm⁻³, such as between about 10¹⁶ cm⁻³ and about 10¹⁸ cm⁻³. After the implant, the photoresist is removed, such as by an acceptable ashing process.

Following the implanting of the region 50P, a photoresist is formed over the fins 52 and the STI regions 56 in the region 50P. The photoresist is patterned to expose the region 50N of the substrate 50, such as the NMOS region. The photoresist can be formed by using a spin-on technique and can be patterned using acceptable photolithography techniques. Once the photoresist is patterned, a p-type impurity implant may be performed in the region 50N, and the photoresist may act as a mask to substantially prevent p-type impurities from being implanted into the region 50P, such as the PMOS region. The p-type impurities may be boron, boron fluoride, indium, or the like implanted in the region to a concentration of equal to or less than 10¹⁸ cm⁻³, such as between about 10¹⁶ cm⁻³ and about 10¹⁸ cm⁻³. After the implant, the photoresist may be removed, such as by an acceptable ashing process.

After the implants of the region 50N and the region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

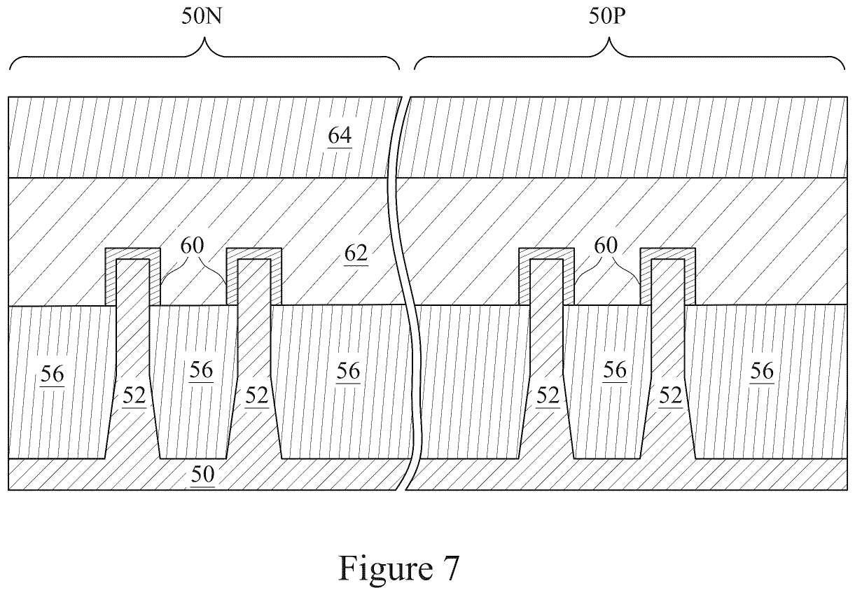

In FIG. 7, a dummy dielectric layer 60 is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The mask layer 64 may be deposited over the dummy gate layer 62. The dummy gate layer 62 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques known and used in the art for depositing the selected material. The dummy gate layer 62 may be made of other materials that have a high etching selectivity from the etching of isolation regions. The mask layer 64 may include, for example, silicon nitride, silicon oxynitride, or the like. In this example, a single dummy gate layer 62 and a single mask layer 64 are formed across the region 50N and the region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending between the dummy gate layer 62 and the STI regions 56.

FIGS. 8A through 15B illustrate various additional steps in the manufacturing of embodiment devices. FIGS. 8A through 15B illustrate features in either of the region 50N and the region 50P. For example, the structures illustrated in FIGS. 8A through 15B may be applicable to both the region 50N and the region 50P. Differences (if any) in the structures of the region 50N and the region 50P are described in the text accompanying each figure.

In FIGS. 8A and 8B, the mask layer 64 (see FIG. 7) may be patterned using acceptable photolithography and etching techniques to form masks 74. The pattern of the masks 74 then may be transferred to the dummy gate layer 62. In some embodiments (not illustrated), the pattern of the masks 74 may also be transferred to the dummy dielectric layer 60 by an acceptable etching technique to form dummy gates 72. The dummy gates 72 cover respective channel regions 58 of the fins 52. The pattern of the masks 74 may be used to physically separate each of the dummy gates 72 from adjacent dummy gates. The dummy gates 72 may also have a lengthwise direction substantially perpendicular to the lengthwise direction of respective epitaxial fins 52.

Further in FIGS. 8A and 8B, gate seal spacers 80 can be formed on exposed surfaces of the dummy gates 72, the masks 74, and/or the fins 52. A thermal oxidation or a deposition followed by an anisotropic etch may form the gate seal spacers 80. The gate seal spacers 80 may be formed of silicon oxide, silicon nitride, silicon oxynitride, or the like.

After the formation of the gate seal spacers 80, implants for lightly doped source/drain (LDD) regions (not explicitly illustrated) may be performed. In the embodiments with different device types, similar to the implants discussed above in FIG. 6, a mask, such as a photoresist, may be formed over the region 50N, while exposing the region 50P, and appropriate type (e.g., p-type) impurities may be implanted into the exposed fins 52 in the region 50P. The mask may then be removed. Subsequently, a mask, such as a photoresist, may be formed over the region 50P while exposing the region 50N, and appropriate type impurities (e.g., n-type) may be implanted into the exposed fins 52 in the region 50N. The mask may then be removed. The n-type impurities may be the any of the n-type impurities previously discussed, and the p-type impurities may be the any of the p-type impurities previously discussed. The lightly doped source/drain regions may have a concentration of impurities of from about 10¹⁵ cm⁻³ to about 10¹⁹ cm⁻³. An anneal may be used to repair implant damage and to activate the implanted impurities.

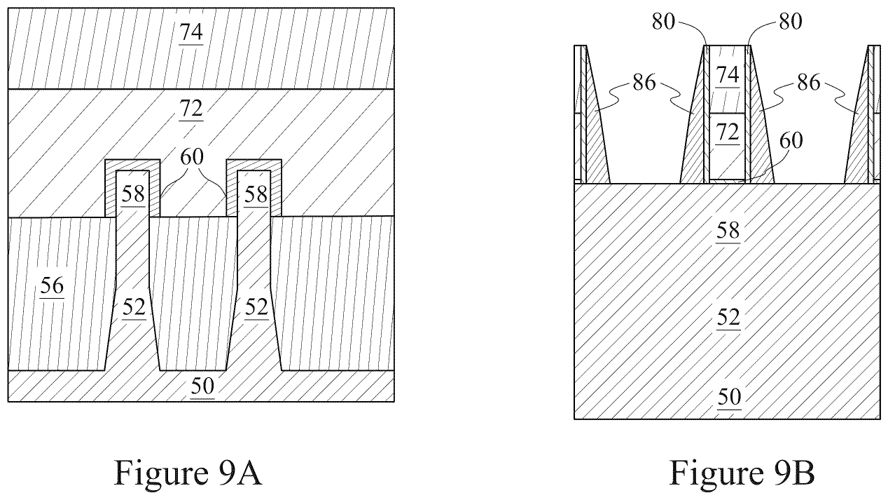

In FIGS. 9A and 9B, gate spacers 86 are formed on the gate seal spacers 80 along sidewalls of the dummy gates 72 and the masks 74. The gate spacers 86 may be formed by conformally depositing an insulating material and subsequently anisotropically etching the insulating material. The insulating material of the gate spacers 86 may be silicon oxide, silicon nitride, silicon oxynitride, silicon carbonitride, a combination thereof, or the like.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86, yielding “L-shaped” gate seal spacers, spacers may be formed and removed, and/or the like. Furthermore, the n-type and p-type devices may be formed using a different structures and steps. For example, LDD regions for n-type devices may be formed prior to forming the gate seal spacers 80 while the LDD regions for p-type devices may be formed after forming the gate seal spacers 80.

In FIGS. 10A and 10B, epitaxial source/drain regions 82 are formed in the fins 52, in accordance with some embodiments. In some cases, the epitaxial source/drain regions 82 may be formed to exert stress in the respective channel regions 58, thereby improving performance. The epitaxial source/drain regions 82 are formed in the fins 52 such that each dummy gate 72 is disposed between respective neighboring pairs of the epitaxial source/drain regions 82. In some embodiments the epitaxial source/drain regions 82 may extend into, and may also penetrate through, the fins 52. In some embodiments, the gate spacers 86 are used to separate the epitaxial source/drain regions 82 from the dummy gates 72 by an appropriate lateral distance so that the epitaxial source/drain regions 82 do not short out subsequently formed gates of the resulting FinFETs.

The epitaxial source/drain regions 82 in the region 50N, e.g., the NMOS region, may be formed by masking the region 50P, e.g., the PMOS region, and etching source/drain regions of the fins 52 in the region 50N to form recesses in the fins 52. Then, the epitaxial source/drain regions 82 in the region 50N are epitaxially grown in the recesses. The epitaxial source/drain regions 82 may include any acceptable material, such as appropriate for n-type FinFETs. For example, if the fin 52 is silicon, the epitaxial source/drain regions 82 in the region 50N may include materials exerting a tensile strain in the channel region 58, such as silicon, silicon carbide, phosphorous doped silicon carbide, silicon phosphide, or the like. The epitaxial source/drain regions 82 in the region 50N may have surfaces raised from respective surfaces of the fins 52 and may have facets.

The epitaxial source/drain regions 82 in the region 50P, e.g., the PMOS region, may be formed by masking the region 50N, e.g., the NMOS region, and etching source/drain regions of the fins 52 in the region 50P to form recesses in the fins 52. Then, the epitaxial source/drain regions 82 in the region 50P are epitaxially grown in the recesses. The epitaxial source/drain regions 82 may include any acceptable material, such as appropriate for p-type FinFETs. For example, if the fin 52 is silicon, the epitaxial source/drain regions 82 in the region 50P may comprise materials exerting a compressive strain in the channel region 58, such as silicon-germanium, boron doped silicon-germanium, germanium, germanium tin, or the like. The epitaxial source/drain regions 82 in the region 50P may also have surfaces raised from respective surfaces of the fins 52 and may have facets.

The epitaxial source/drain regions 82 and/or the fins 52 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 82 may be in situ doped during growth.

As a result of the epitaxy processes used to form the epitaxial source/drain regions 82 in the region 50N and the region 50P, upper surfaces of the epitaxial source/drain regions have facets which expand laterally outward beyond sidewalls of the fins 52. In some embodiments, these facets cause adjacent source/drain regions 82 of a same FinFET to merge as illustrated by FIG. 10C. In other embodiments, adjacent source/drain regions 82 remain separated after the epitaxy process is completed as illustrated by FIG. 10D. In the embodiments illustrated in FIGS. 10C and 10D, gate spacers 86 are formed covering a portion of the sidewalls of the fins 52 that extend above the STI regions 56 thereby blocking the epitaxial growth. In some other embodiments, the spacer etch used to form the gate spacers 86 may be adjusted to remove the spacer material to allow the epitaxially grown region to extend to the surface of the STI region 56.

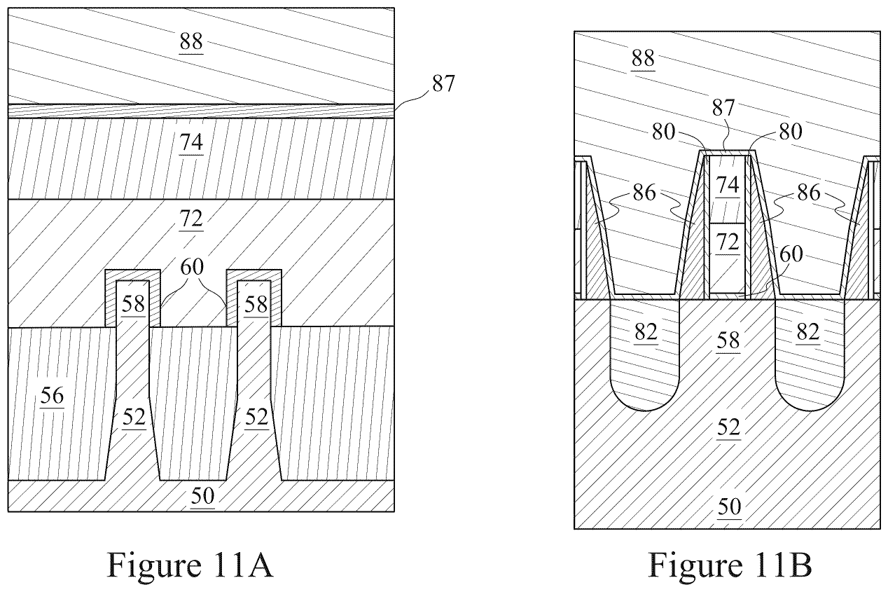

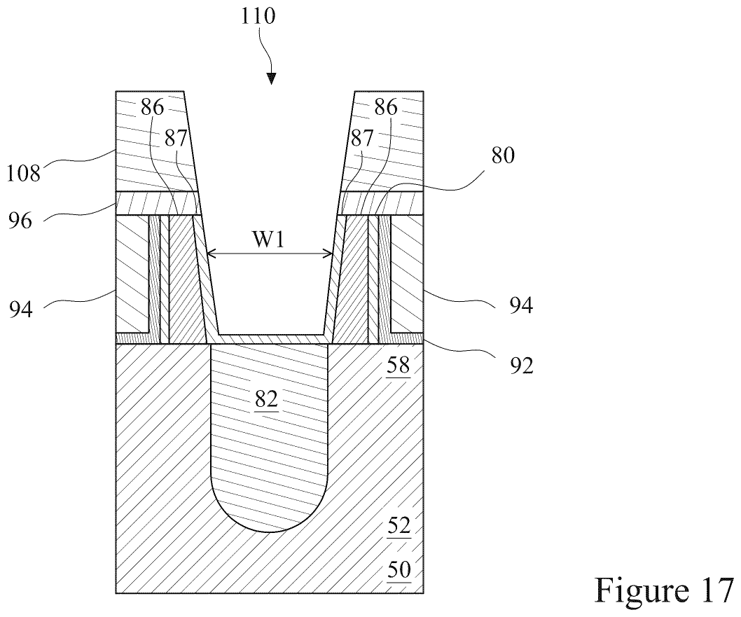

In FIGS. 11A and 11B, a first interlayer dielectric (ILD) 88 is deposited over the structure illustrated in FIGS. 10A and 10B, in accordance with some embodiments. The first ILD 88 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 87 is disposed between the first ILD 88 and the epitaxial source/drain regions 82, the masks 74, and the gate spacers 86. The CESL 87 may comprise a dielectric material, such as silicon nitride, silicon oxide, silicon oxynitride, or the like, and may have a different etch rate than the material of the overlying first ILD 88. In some embodiments, the CESL 87 may be formed having a thickness between about 2 nm and about 5 nm, such as about 3 nm. In some cases, controlling the thickness of the CESL 87 can control the size (e.g., width or height) of the source/drain contacts 118 and/or the size (e.g., width or height) of the air gaps 120 formed subsequently (see FIGS. 17-22).

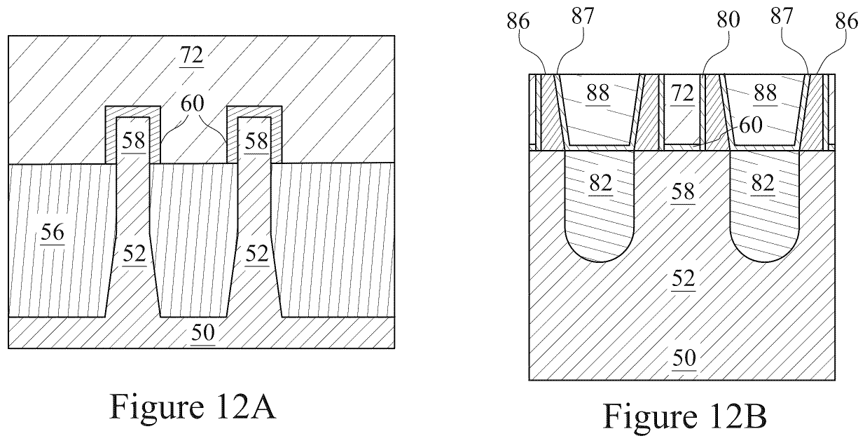

In FIGS. 12A and 12B, a planarization process, such as a CMP, may be performed to level the top surface of the first ILD 88 with the top surfaces of the dummy gates 72 or the masks 74. The planarization process may also remove the masks 74 on the dummy gates 72, and portions of the gate seal spacers 80 and the gate spacers 86 along sidewalls of the masks 74. After the planarization process, top surfaces of the dummy gates 72, the gate seal spacers 80, the gate spacers 86, and the first ILD 88 are level. Accordingly, the top surfaces of the dummy gates 72 are exposed through the first ILD 88. In some embodiments, the masks 74 may remain, in which case the planarization process levels the top surface of the first ILD 88 with the top surfaces of the masks 74.

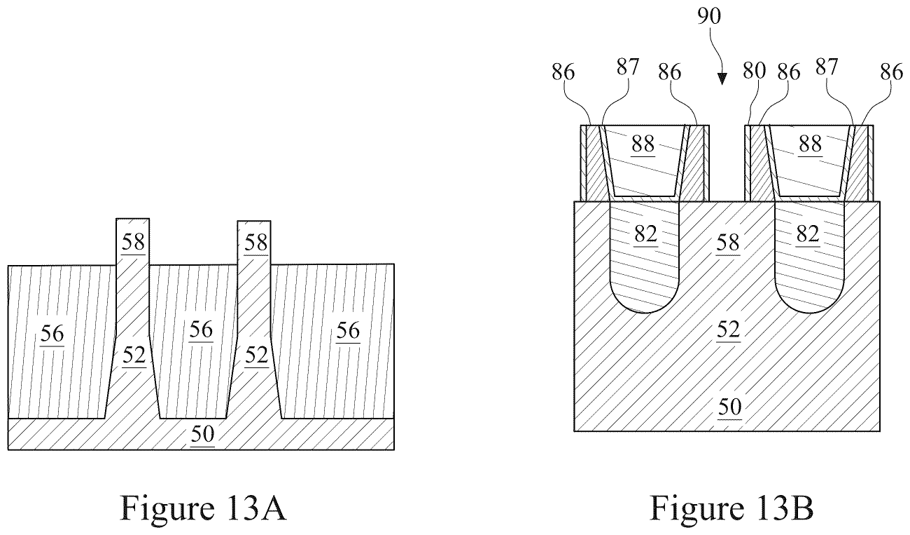

In FIGS. 13A and 13B, the dummy gates 72, and the masks 74 if present, are removed in one or more etching steps, so that recesses 90 are formed. Portions of the dummy dielectric layer 60 in the recesses 90 may also be removed. In some embodiments, only the dummy gates 72 are removed and the dummy dielectric layer 60 remains and is exposed by the recesses 90. In some embodiments, the dummy dielectric layer 60 is removed from recesses 90 in a first region of a die (e.g., a core logic region) and remains in recesses 90 in a second region of the die (e.g., an input/output region). In some embodiments, the dummy gates 72 are removed by an anisotropic dry etch process. For example, the etching process may include a dry etch process using one or more reaction gases that selectively etch the dummy gates 72 without etching the first ILD 88, the gate spacers 86, or the CESL 87. Each recess 90 exposes and/or overlies a channel region 58 of a respective fin 52. Each channel region 58 is disposed between neighboring pairs of the epitaxial source/drain regions 82. During the removal, the dummy dielectric layer 60 may be used as an etch stop layer when the dummy gates 72 are etched. The dummy dielectric layer 60 may then be optionally removed after the removal of the dummy gates 72.

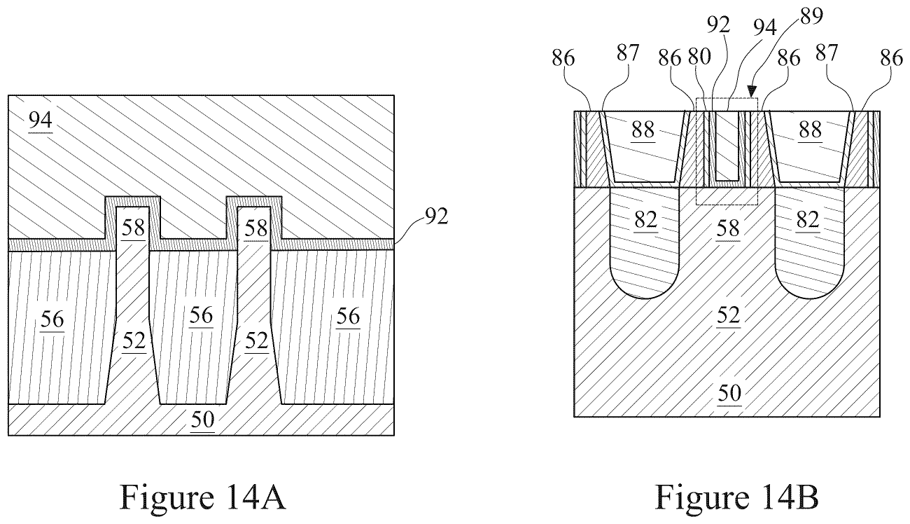

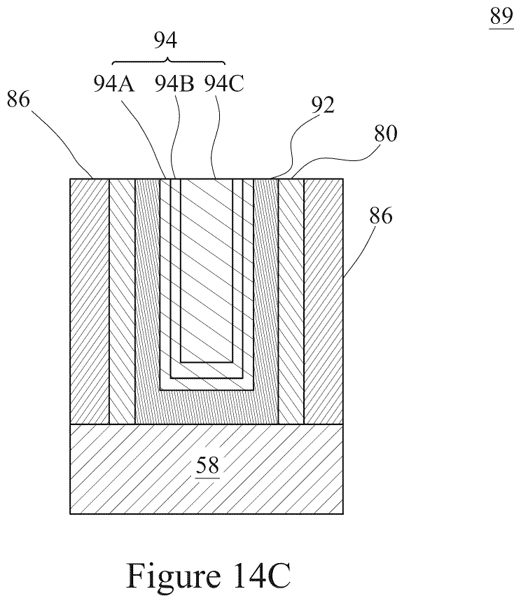

In FIGS. 14A and 14B, gate dielectric layers 92 and gate electrodes 94 are formed for replacement gates. FIG. 14C illustrates a detailed view of region 89 of FIG. 14B. Gate dielectric layers 92 are deposited conformally in the recesses 90, such as on the top surfaces and the sidewalls of the fins 52 and on sidewalls of the gate seal spacers 80/gate spacers 86. The gate dielectric layers 92 may also be formed on the top surface of the first ILD 88. In accordance with some embodiments, the gate dielectric layers 92 comprise silicon oxide, silicon nitride, or multilayers thereof. In some embodiments, the gate dielectric layers 92 include a high-k dielectric material, and in these embodiments, the gate dielectric layers 92 may have a k value greater than about 7.0, and may include a metal oxide or a silicate of hafnium, aluminum, zirconium, lanthanum, manganese, barium, titanium, lead, and combinations thereof. The formation methods of the gate dielectric layers 92 may include Molecular-Beam Deposition (MBD), ALD, PECVD, and the like. In embodiments where portions of the dummy dielectric layer 60 remains in the recesses 90, the gate dielectric layers 92 include a material of the dummy dielectric layer 60 (e.g., silicon oxide).

The gate electrodes 94 are deposited over the gate dielectric layers 92, respectively, and fill the remaining portions of the recesses 90. The gate electrodes 94 may include a metal-containing material such as titanium nitride, titanium oxide, tantalum nitride, tantalum carbide, cobalt, ruthenium, aluminum, tungsten, combinations thereof, or multi-layers thereof. For example, although a single layer gate electrode 94 is illustrated in FIG. 14B, the gate electrode 94 may comprise any number of liner layers 94A, any number of work function tuning layers 94B, and a fill material 94C as illustrated by FIG. 14C. After the filling of the recesses 90, a planarization process, such as a CMP, may be performed to remove the excess portions of the gate dielectric layers 92 and the material of the gate electrodes 94, which excess portions are over the top surface of the first ILD 88. The remaining portions of material of the gate electrodes 94 and the gate dielectric layers 92 thus form replacement gates of the resulting FinFETs. The gate electrodes 94 and the gate dielectric layers 92 may be collectively referred to as a “gate stack.” The gate and the gate stacks may extend along sidewalls of a channel region 58 of the fins 52.

The formation of the gate dielectric layers 92 in the region 50N and the region 50P may occur simultaneously such that the gate dielectric layers 92 in each region are formed from the same materials, and the formation of the gate electrodes 94 may occur simultaneously such that the gate electrodes 94 in each region are formed from the same materials. In some embodiments, the gate dielectric layers 92 in each region may be formed by distinct processes, such that the gate dielectric layers 92 may be different materials, and/or the gate electrodes 94 in each region may be formed by distinct processes, such that the gate electrodes 94 may be different materials. Various masking steps may be used to mask and expose appropriate regions when using distinct processes.

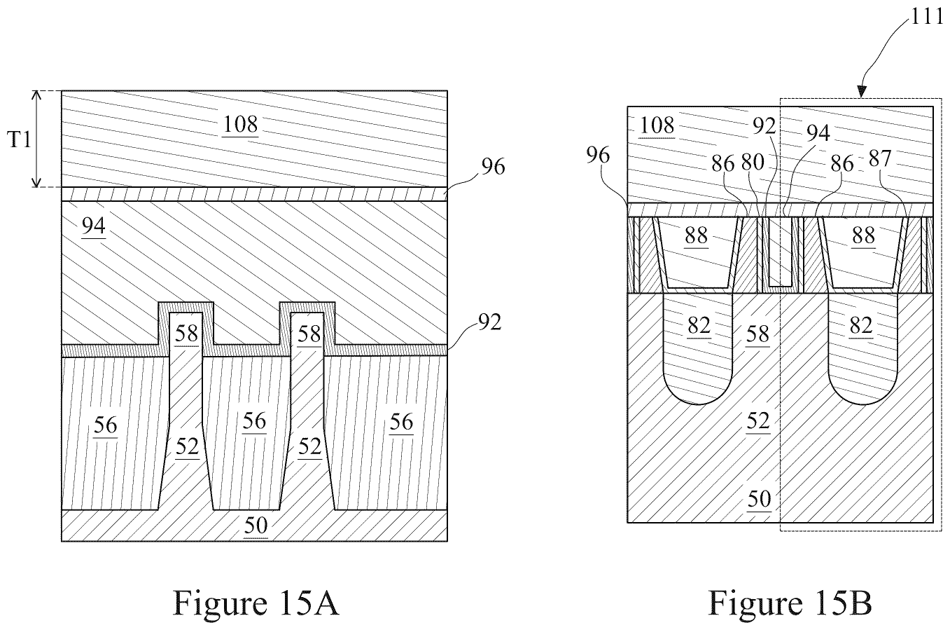

In FIGS. 15A and 15B, a second ILD 108 is deposited over the first ILD 88, in accordance with some embodiments. In some embodiments, the second ILD 108 is a flowable film formed by a flowable CVD method. In some embodiments, the second ILD 108 is formed of a dielectric material such as PSG, BSG, BPSG, USG, silicon oxide, or the like, and may be deposited by any suitable method, such as CVD, PECVD, or the like. A planarization process, such as a CMP, may be performed to planarize a surface of the second ILD 108. In some embodiments, the second ILD 108 may be formed having a thickness T1 between about 10 nm and about 30 nm, though other thicknesses are possible.

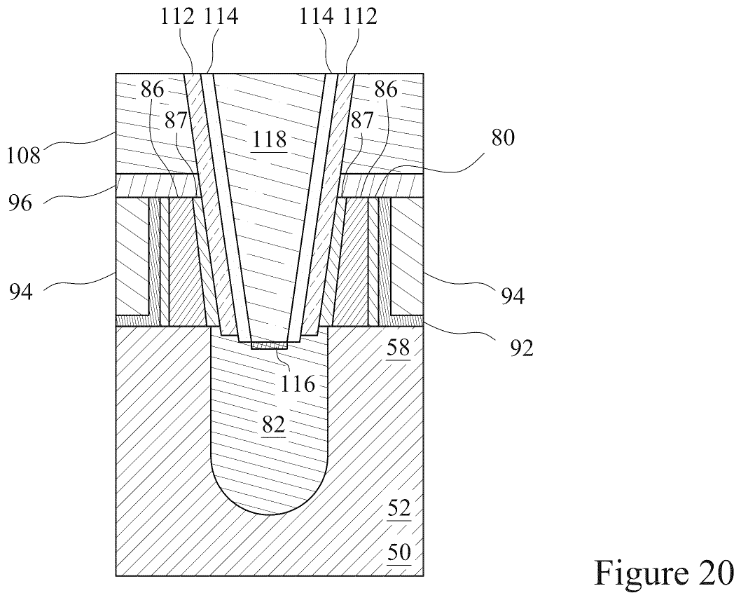

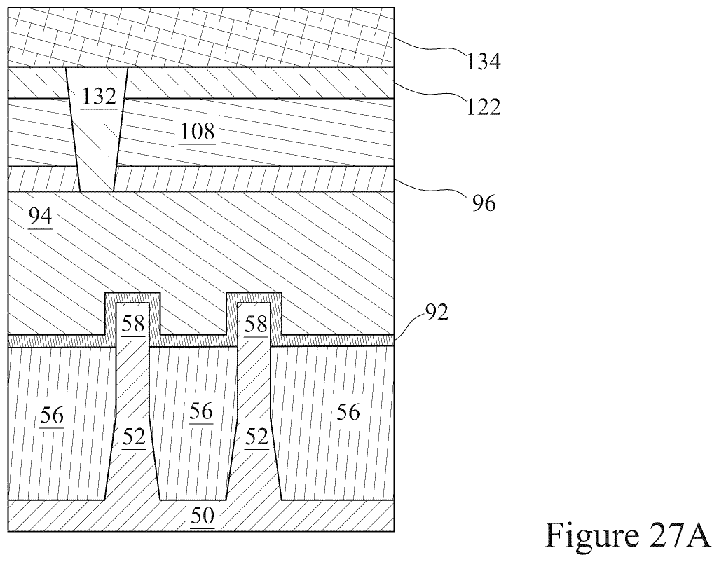

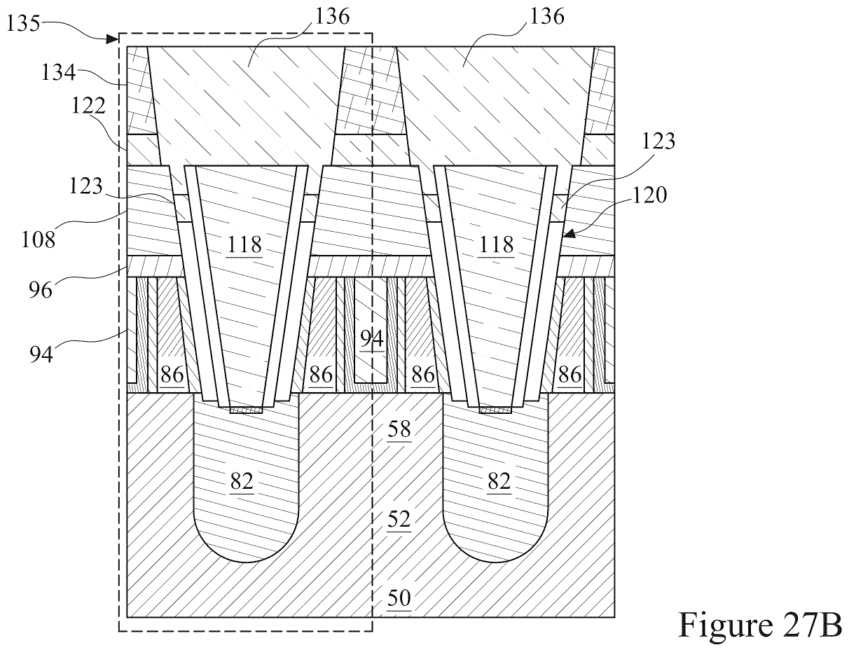

In accordance with some embodiments, a hard mask 96 is deposited over the structure before depositing the second ILD 108. The hard mask 96 may comprise one or more layers of dielectric material, such as silicon nitride, silicon oxynitride, or the like, and may have a different etch rate than the material of the overlying second ILD 108. In some embodiments, the hard mask 96 may be formed having a thickness between about 2 nm and about 4 nm. In some embodiments, the hard mask 96 is formed of the same material as the CESL 87 or is formed having about the same thickness as the CESL 87. The subsequently formed source/drain contacts 118 (see FIG. 20) penetrate through the hard mask 96 and the CESL 87 to contact a top surface of the epitaxial source/drain regions 82, and the gate contacts 132 (see FIG. 27A) penetrate through the hard mask 96 to contact a top surface of the gate electrode 94.

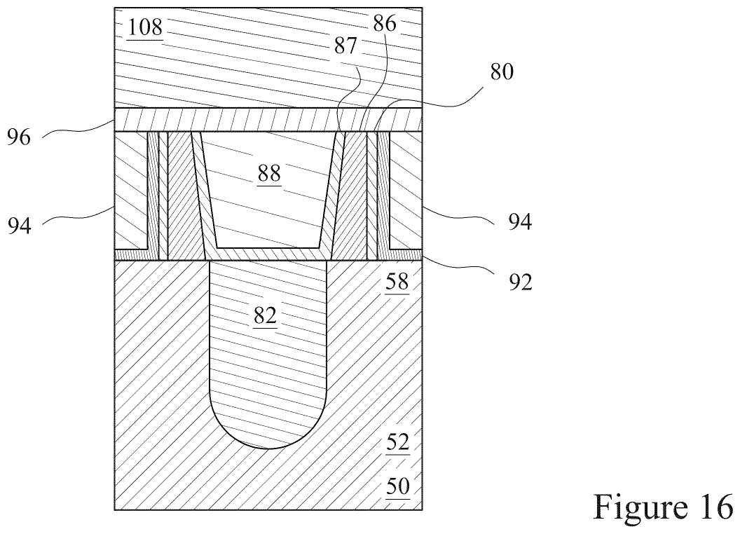

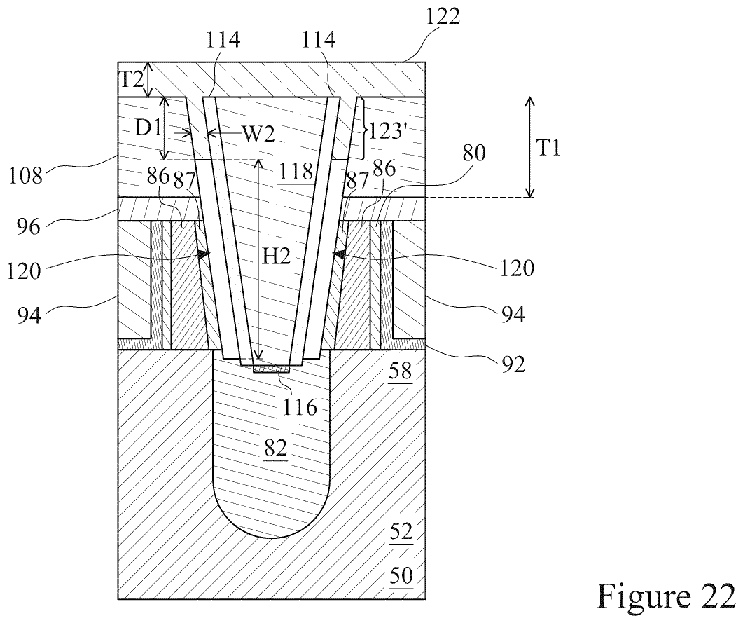

FIGS. 16 through 22 illustrate intermediate steps in the formation of source/drain contacts 118 with air gaps 120 (see FIG. 22), in accordance with some embodiments. The source/drain contacts 118 physically and electrically contact the epitaxial source/drain regions 82. The source/drain contacts 118 may also be referred to as “contacts 118” or “contact plugs 118.” For clarity, FIGS. 16 through 22 are shown as a detailed view of region 111 of FIG. 15B. FIG. 16 illustrates the region 111 of the same structure shown in FIG. 15B.

In FIG. 17, openings 110 are formed in the first ILD 88 and second ILD 108 to expose the epitaxial source/drain regions 82, in accordance with some embodiments. The openings 110 may be formed using suitable photolithography and etching techniques. For example, a photoresist (e.g., a single layer or multi-layer photoresist structure) may be formed over the second ILD 108. The photoresist may then be patterned to expose the second ILD 108 in regions corresponding to the openings 110. One or more suitable etching processes may then be performed to etch the openings 110, using the patterned photoresist as an etching mask. The one or more etching processes may include wet etching processes and/or dry etching processes. In some embodiments, the CESL 87 and/or the hard mask 96 may be used as an etch stop layer when forming the openings 110. In some embodiments, portions of the CESL 87 extending over the epitaxial source/drain regions 82 may also be removed. In some embodiments in which the openings extend through the CESL 87, the openings 110 may extend below a top surface of the epitaxial source/drain regions 82 and into the epitaxial source/drain regions 82. In some embodiments, the one or more etching processes may remove the material of the first ILD 88 to expose the CESL 87, and may also partially etch portions of the CESL 87 over the epitaxial source/drain regions 82. The openings 110 may have tapered sidewalls as shown in FIG. 17 or may have sidewalls having a different profile (e.g., vertical sidewalls). In some embodiments, the openings 110 may have a width W1 that is between about 10 nm and about 30 nm, though other widths are possible. The width W1 may be measured across the top of the openings 110, across the bottom of the openings 110, or across the openings 110 at any other location. In some cases, controlling the width W1 can control the size of the source/drain contacts 118 and/or the size of the air gaps 120 formed subsequently (see FIG. 22).

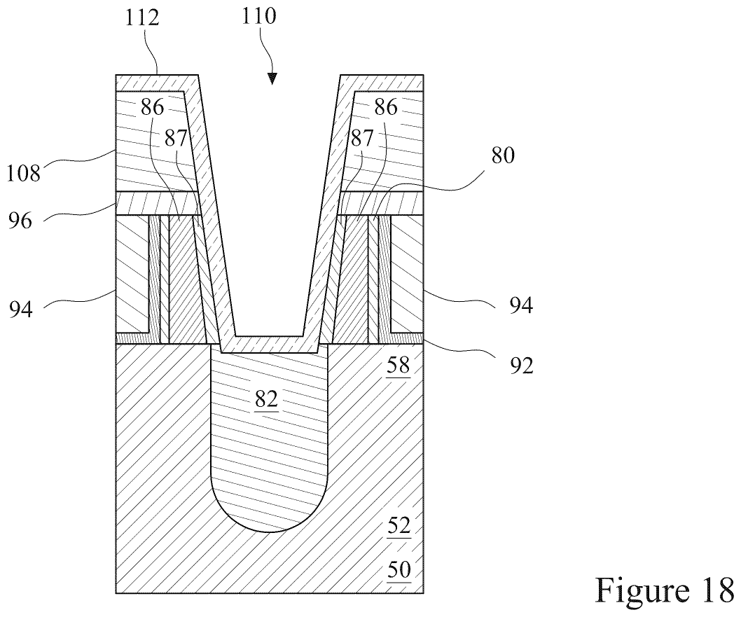

In FIG. 18, a dummy spacer layer 112 is formed over the openings 110, in accordance with some embodiments. In some embodiments, an etching process is first performed to remove the CESL 87 over the epitaxial source/drain regions 82. The etching process may include, for example, an anisotropic dry etching process. The etching process may extend the openings 110 below a top surface of the epitaxial source/drain regions 82 and into the epitaxial source/drain regions 82. The dummy spacer layer 112 may then be formed as a blanket layer that extends over the second ILD 108, the CESL 87, and the epitaxial source/drain regions 82, in some embodiments. The dummy spacer layer 112 may comprise a material such as silicon, polysilicon, amorphous silicon, the like, or a combination thereof. In some embodiments, the dummy spacer layer 112 is a material that can be etched with a high selectivity relative to other layers, such as the second ILD 108, the CESL 87, or the contact spacer layer 114 (described below). The dummy spacer layer 112 may be deposited by PVD, CVD, ALD, or the like. In some embodiments, the dummy spacer layer 112 may be formed having a thickness between about 3 nm and about 9 nm, although other thicknesses are possible. In some embodiments, the thickness of the dummy spacer layer 112 corresponds to about the width W2 of the subsequently formed air gaps 120 (see FIG. 22).

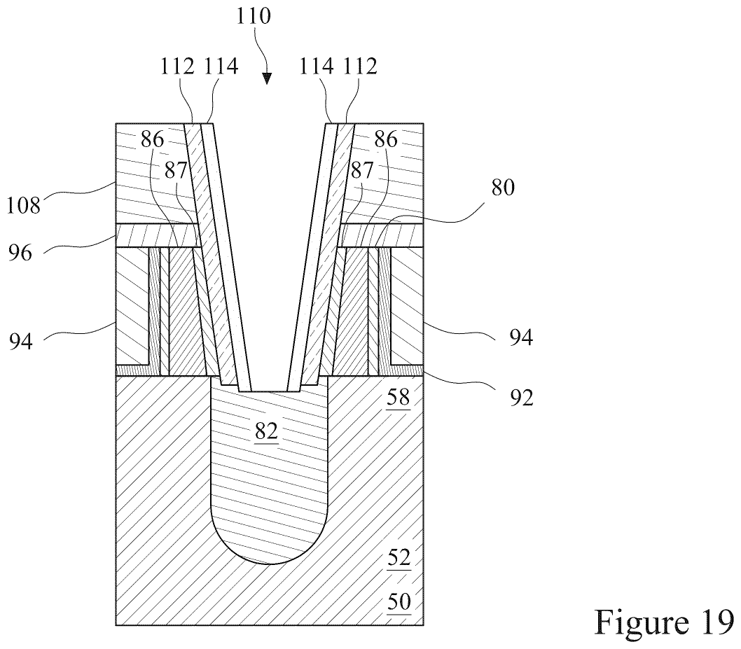

In FIG. 19, a contact spacer layer 114 is formed on the dummy spacer layer 112, in accordance with some embodiments. Prior to forming the contact spacer layer 114, a suitable anisotropic dry etching process may be performed to remove regions of the dummy spacer layer 112 extending laterally over the second ILD 108 and the epitaxial source/drain regions 82. Due to the anisotropy of the dry etching process, regions of the dummy spacer layer 112 extending along sidewalls of the openings 110 remain. In some embodiments, the anisotropic dry etching process may also etch the material of the epitaxial source/drain regions 82 and thus extend the openings 110 further into the epitaxial source/drain regions 82.

The contact spacer layer 114 may be formed as a blanket layer that extends over the second ILD 108, dummy spacer layer 112, and the epitaxial source/drain regions 82, in some embodiments. The contact spacer layer 114 may comprise one or more layers of materials such as silicon oxide, silicon nitride, silicon oxynitride, silicon carbonitride, the like, or a combination thereof. The contact spacer layer 114 may be deposited by PVD, CVD, ALD, or the like. In some embodiments, the contact spacer layer 114 may be formed having a thickness between about 2 nm and about 5 nm, such as about 3 nm, although other thicknesses are possible. After forming the contact spacer layer 114, a suitable anisotropic dry etching process may be performed to remove regions of the contact spacer layer 114 extending laterally over the second ILD 108, the dummy spacer layer 112, and the epitaxial source/drain regions 82. Due to the anisotropy of the dry etching process, regions of the contact spacer layer 114 extending along sidewalls of the openings 110 (e.g., extending along the dummy spacer layer 112) remain. In some cases, controlling the thickness of the contact spacer layer 114 can control the size of the source/drain contacts 118 and/or the size of the air gaps 120 formed subsequently (see FIG. 22).

Turning to FIG. 20, one or more conductive materials are deposited in the openings 110, forming source/drain contacts 118, in accordance with some embodiments. In some embodiments, the conductive materials of the source/drain contacts 118 include a liner (not separately shown) conformally deposited on surfaces of the openings 110 (e.g., on the contact spacer layer 114) and a conductive fill material deposited on the liner to fill the openings 110. In some embodiments, the liner comprises titanium, cobalt, nickel, titanium nitride, titanium oxide, tantalum nitride, tantalum oxide, the like, or a combination thereof. In some embodiments, the conductive fill material comprises cobalt, tungsten, copper, aluminum, gold, silver, alloys thereof, the like, or combinations thereof. The liner or the conductive fill material may be deposited using one or more suitable processes, such as CVD, PVD, ALD, sputtering, plating, or the like.

In some embodiments, silicide regions 116 may also be formed on upper portions of the epitaxial source/drain regions 82 to improve electrical connection between the epitaxial source/drain regions 82 and the source/drain contacts 118. In some embodiments, silicide regions 116 may be formed by reacting upper portions of the epitaxial source/drain regions 82 with the liner. In some embodiments, a separate material may be deposited on the epitaxial source/drain regions 82 to be reacted with the epitaxial source/drain regions 82 to form silicide regions 116. The silicide regions 116 may comprise a titanium silicide, a nickel silicide, the like, or a combination thereof. In some embodiments, one or more annealing processes are performed to facilitate the silicide formation reaction. After the conductive fill material for the source/drain contacts 118 is deposited, excess material may be removed by using a planarization process, such as a CMP, to form top surfaces of the source/drain contacts 118 coplanar with the top surface of the second ILD 108.

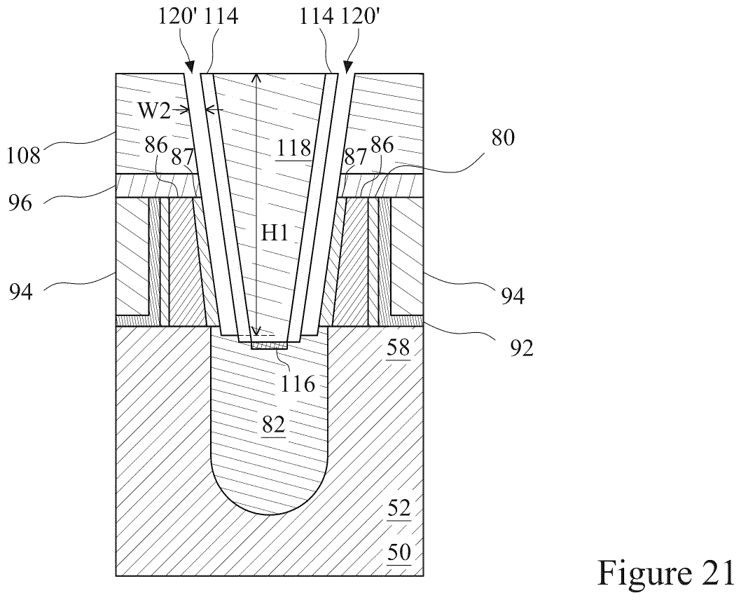

Turning to FIG. 21, the material of the dummy spacer layer 112 is removed to form initial air gaps 120′, in accordance with some embodiments. The material of the dummy spacer layer 112 may be removed using a suitable etching process, such as a dry etching process. The etching process may be selective to the material of the dummy spacer layer 112 over the material of the second ILD 108, the CESL 87, or the contact spacer layer 114. For example, in an embodiment in which the dummy spacer layer 112 comprises silicon and the contact spacer layer 114 comprises silicon nitride, the etching process may include using HBr, O₂, He, CH₃F, H₂, the like, or combinations thereof as process gases in a plasma etching process that selectively etches the silicon of the dummy spacer layer 112. Other materials or etching processes are possible.

In some embodiments, the initial air gaps 120′ may be formed having a width W2 between about 0.5 nm and about 4 nm, although other widths are possible. In some cases, forming the initial air gaps 120′ having a larger width W2 can result in reduced capacitance and improved device performance, described in greater detail below. The initial air gaps 120′ may have a substantially uniform width or the width may vary along their vertical length (e.g., the length extending away from substrate 50). For example, the width of the initial air gaps 120′ may taper, such as having a smaller width near the bottom (e.g., near the epitaxial source/drain regions 82) than near the top (e.g., near the second ILD 108). In some embodiments, the bottom of the initial air gaps 120′ may extend into the epitaxial source/drain regions 82 (as shown in FIG. 21), or the initial air gaps 120′ may have a bottom at or above a top surface of the epitaxial source/drain regions 82. The initial air gaps 120′ may extend at an angle relative to a vertical axis, as shown in FIG. 21, or may extend substantially along a vertical axis. In some embodiments, the initial air gaps 120′ may extend a vertical height H1 (e.g., a distance H1 along a vertical axis) that is between about 15 nm and about 80 nm, although other heights are possible.

In some cases, by forming the initial air gaps 120′ (and the subsequently formed air gaps 120 shown in FIG. 22) between the source/drain contact 118 and the gate stack 92/94, the capacitance between the source/drain contact 118 and the gate stack 92/94 may be reduced. The capacitance may be reduced in this manner due to the lower dielectric constant (k-value) of air, about k=1, relative to other spacer materials such as oxides, nitrides, or the like. By reducing the capacitance using the air gaps 120, the FinFET device may have faster response speeds and improved performance at higher frequency operation.

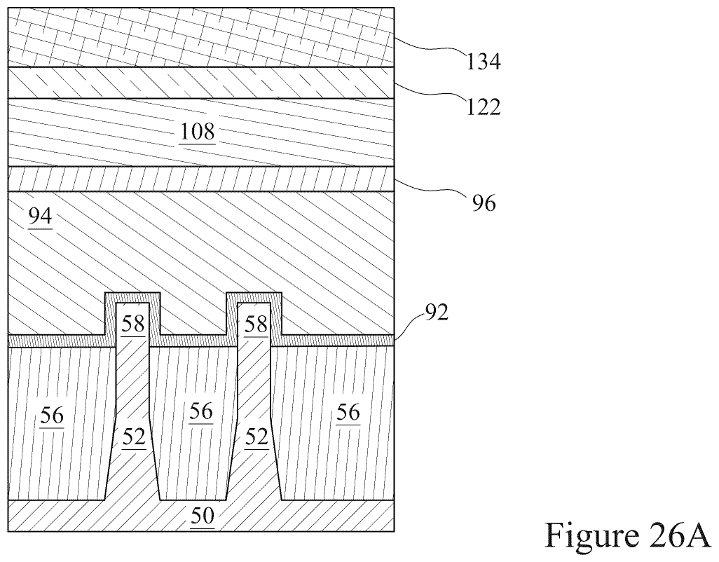

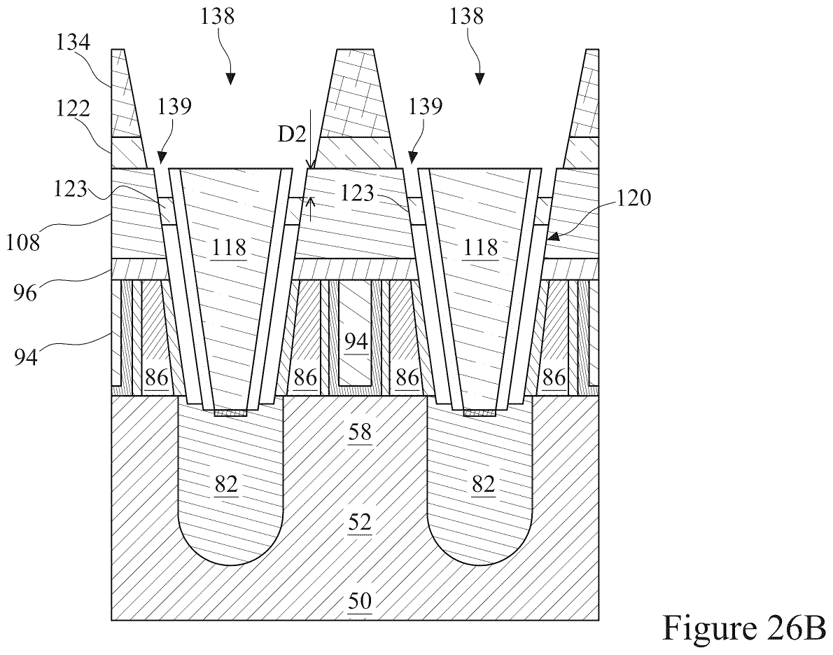

Turning to FIG. 22, an etch stop layer (ESL) 122 is formed over the second ILD 108, the source/drain contacts 118, and over the initial air gaps 120′. The ESL 122 may be formed as a blanket layer extending across the initial air gaps 120′, such that the initial air gaps 120′ are enclosed and form air gaps 120. In some embodiments, some of the material of the ESL 122 partially extends into the initial air gaps 120′. The ESL 122 may be subsequently used as an etch stop layer during the formation of conductive features 136 on the source/drain contacts 118, described below for FIGS. 26A-B and 27A-B.

The ESL 122 may comprise one or more layers of materials such as silicon nitride, silicon oxynitride, silicon carbonitride, silicon oxycarbonitride, the like, or a combination thereof, and may be deposited using, for example, an ALD process (e.g., a thermal ALD process or a plasma-enhanced ALD (PEALD) process). In some embodiments, the ESL 122 may be formed having a thickness T2 over the second ILD 108 that is between about 3 nm and about 30 nm, although other thicknesses are possible. In some embodiments, the ESL 122 may be deposited such that material of the ESL 122 is formed extending into and sealing the initial air gaps 120′. The portions of the ESL 122 that extend into the initial air gaps 120′ are indicated in FIG. 22 and subsequent figures as sealing regions 123′. In some embodiments, the sealing regions 123′ may extend into the initial air gaps 120′ a vertical distance D1 that is between about 2 nm and about 20 nm, though other distances are possible. In some cases, the distance D1 may be less than, about the same, or greater than the thickness T1 of the second ILD 108. In some embodiments, the distance D1 may be controlled by controlling parameters of the ESL 122 material deposition process, described in greater detail below.

The remaining portions of the initial air gaps 120′ that are sealed by the sealing regions 123′ are indicated in FIG. 22 and subsequent figures as air gaps 120. In some embodiments, the air gaps 120 may extend a vertical height H2 that is between about 10 nm and about 80 nm, although other distances are possible. By controlling the deposition of the ESL 122 such that sealing regions 123′ extend into the initial air gaps 120′, subsequently deposited conductive material of the conductive features 136 (see FIG. 27B) may be blocked from filling or partially filling the initial air gaps 120′, and thus capacitive benefits of the air gaps may be preserved while also reducing the chance of leakage between the conductive features 136 and the gate stack 92/94. For example, forming the air gaps 120 between the source/drain contacts 118 and the gate stack 92/94 of a FinFET device may reduce the parasitic capacitance between the source/drain contacts 118 and the gate stack 92/94 which can improve high-speed operation of the FinFET. Additionally, the presence of the air gaps 120 reduces that chance of leakage between the source/drain contacts 118 and the gate stack 92/94 or between subsequently-formed conductive features 136 (see FIG. 27B) and the gate stack 92/94. By controlling the distance D1 of the sealing regions 123′, the size of the subsequently formed air gaps 120 may be controlled. For example, in some cases, a smaller distance D1 may allow for larger air gaps 120, which can further reduce parasitic capacitance or leakage.

In some embodiments in which an ALD process is used to deposit the material of the ESL 122, the parameters of the ALD process may be controlled to control the distance D1 that the sealing regions 123′ extend into the initial air gaps 120′. In some embodiments, the distance D1 may be controlled by controlling the dose (e.g., the pressure and/or pulse duration) of one or more precursors of the ALD process. For example, a larger dose of a precursor can allow that precursor to reach and react with surfaces deeper within the initial air gaps 120′. In this manner, larger doses of precursors may allow the material of the ESL 122 to grow on surfaces extending further into the initial air gaps 120′. Accordingly, smaller doses of precursors may limit the growth of the material of the ESL 122 to surfaces near the top of the initial air gaps 120′. In this manner, by controlling the dose of one or more of the precursors, the distance into the initial air gaps 120′ that the material of the ESL 122 is grown may be controlled, and thus the distance D1 that the sealing regions 123′ extend into the initial air gaps 120′ may be controlled.

In some embodiments, by using a smaller dose of a precursor, that precursor may be unable to reach all surfaces (e.g., the bottom) of the initial air gaps 120′ during an ALD half-cycle, and thus not all potential surface reaction sites are reacted with that precursor during the ALD half-cycle. In this manner, the ALD process is not limited by saturation of surface reaction sites but is limited by the precursor dose, and the ALD process described herein may be considered a “non-saturating” or “low-dose” ALD process. Additionally, by using smaller precursor doses, the material of the ESL 122 can be controlled to not fill the initial air gaps 120′ but to grow on upper surfaces of the initial air gaps 120′ to form air gaps 120 sealed by sealing regions 123′. In this manner, the non-saturating ALD process described herein can seal the initial air gaps 120′ with reduced risk of filling the initial air gaps 120′ with material.

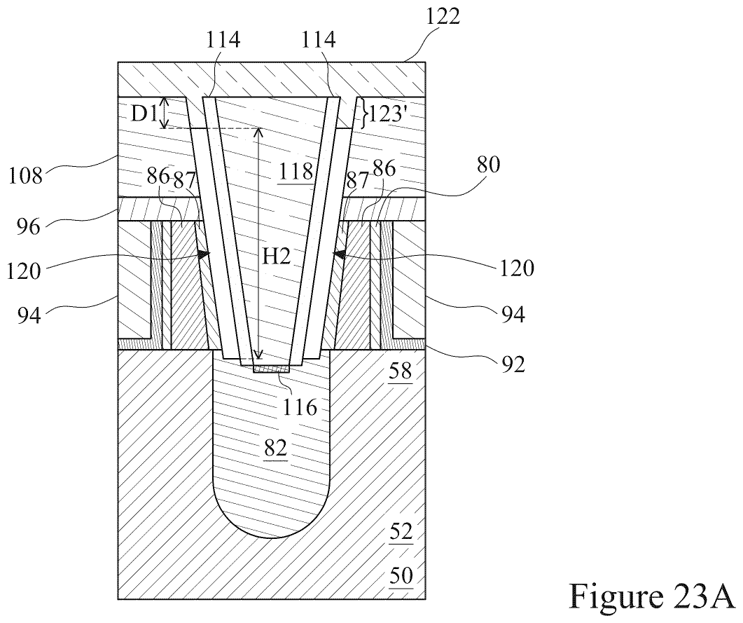

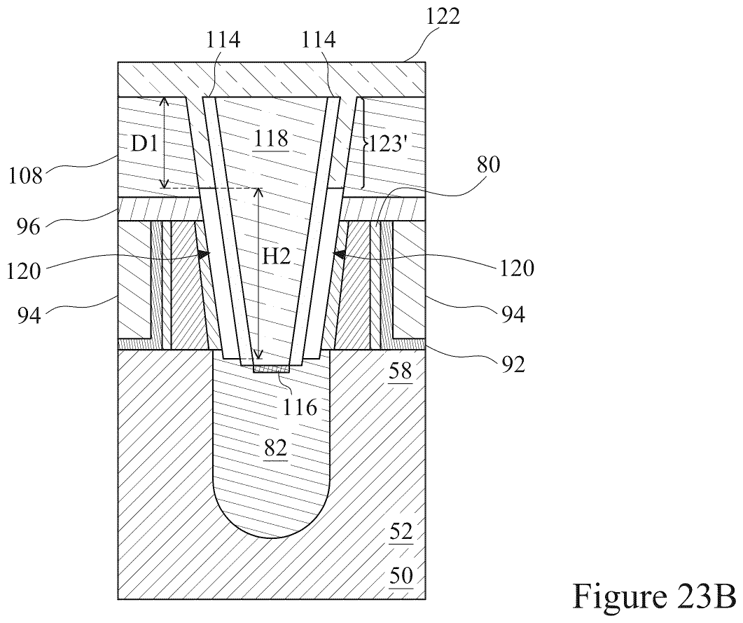

FIGS. 23A and 23B illustrate structures similar to that shown in FIG. 22, but FIG. 23A shows an embodiment in which the sealing regions 123′ are formed having a smaller distance D1 and FIG. 23B shows an embodiment in which the sealing regions 123′ are formed having a larger distance D1. In some embodiments, the parameters of the non-saturated ALD process described herein may be controlled to control the distance D1 of the sealing regions 123′. For example, the dose (e.g., pressure and/or pulse duration) of a precursor of a half-cycle may be controlled to control formation of the sealing regions 123′. The use of a smaller precursor dose (e.g., smaller precursor pressure and/or shorter pulse duration) may form sealing regions 123′ extending a smaller distance D1 into the initial air gaps 120′, similar to the sealing regions 123′ shown in FIG. 23A. The use of a larger precursor dose (e.g., larger precursor pressure and/or longer pulse duration) may form sealing regions 123′ extending a larger distance D1 into the initial air gaps 120′, similar to the sealing regions 123′ shown in FIG. 23B. In this manner, controlling the precursor dose can control the distance D1 that the sealing regions 123′ extend into the initial air gaps 120′.

As another example, for embodiments in which the ALD process is a PEALD process, the duration of time that the RF power is applied in a half-cycle may be controlled to control formation of the sealing regions 123′. As decreasing the RF duration decreases the number of reactive precursor species generated, a shorter RF power duration may form sealing regions 123′ extending a smaller distance D1, similar to the sealing regions 123′ shown in FIG. 23A. A longer RF power duration may form sealing regions 123′ extending a larger distance D1, similar to the sealing regions 123′ shown in FIG. 23B. In some embodiments, a shorter precursor pulse duration combined with a shorter RF power duration may form sealing regions 123′ with a smaller distance D1 than a longer precursor pulse duration combined with a longer RF power duration. These are examples, and the precursor pressure, pulse duration, RF power duration, and/or other parameters may be controlled in other combinations or other variations to control the formation of the sealing regions 123′. The parameters or precursors of different portions of an ALD cycle may be controlled in this manner, and in some embodiments, the same portions of different ALD cycles of a deposition process may have different parameters. The sealing regions 123′ and the respective distances D1 shown in FIGS. 22, 23A, and 23B are illustrative examples, and sealing regions 123′ may be formed having different distances D1 than shown.

As an illustrative example, a PEALD process may be used to deposit the ESL 122 (and sealing regions 123′) comprising silicon nitride. Silicon-forming precursors such as SiH₄, SiH₂Cl₂, SiH₂I₂, the like, or combinations thereof may be used for the silicon-forming half-cycle, and nitrogen-forming precursors such as N₂, NH₃, the like, or combinations thereof may be used during a nitrogen-forming half-cycle in which a plasma is generated. Other precursors than these may be used in other embodiments. The deposition may be performed in a process chamber at a process temperature between about 250° C. and about 400° C., though other temperatures may be used. In some embodiments, in a silicon-forming half-cycle, the silicon-forming precursor may be pulsed into the process chamber at a flow rate between about 5 sccm and about 100 sccm, for a pulse duration that is between about 0.1 seconds and 0.5 seconds. The silicon-forming half-cycle may have a pressure that is between about 10 Torr and about 30 Torr. After pulsing the silicon-forming precursor, a purge may be performed for between about 0.1 seconds and about 5 seconds. In some embodiments, in a nitrogen-forming half-cycle, the nitrogen-forming precursor may be pulsed into the process chamber at a flow rate between about 10 sccm and about 500 sccm, for a pulse duration that is between about 0.1 seconds and 1 second. The nitrogen-forming half-cycle may have a pressure that is between about 10 Torr and about 30 Torr. A plasma may be generated by RF power for between about 0.1 seconds and about 1 second. The plasma may be generated by an RF power that is between about 100 Watts and about 800 Watts. After pulsing the nitrogen-forming precursor, a purge may be performed for between about 0.1 seconds and about 1 second. These are example parameter values, and other parameter values or parameter values in combinations other than these examples may be used in other embodiments.

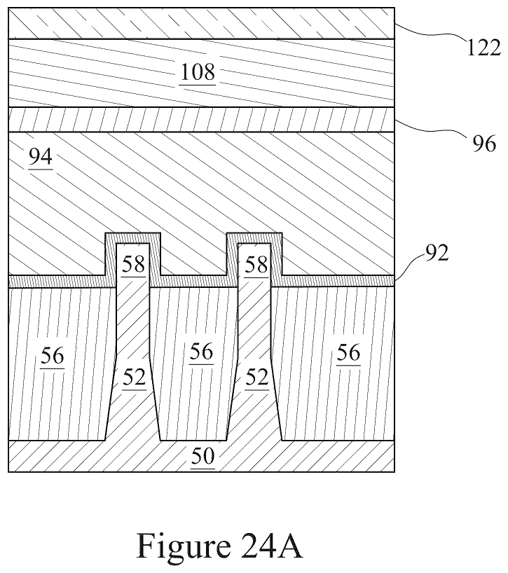

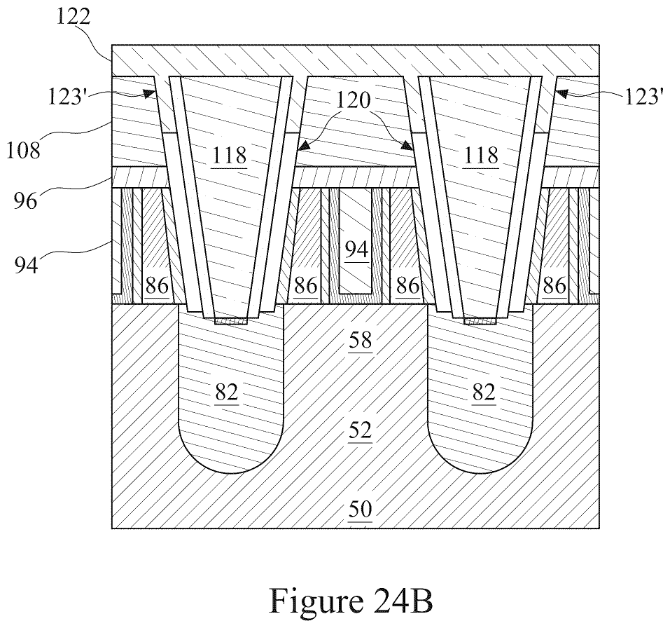

FIGS. 24A through 27B are cross-sectional views of additional stages in the manufacturing of FinFETs, in accordance with some embodiments. FIGS. 24A through 27B show the same cross-sectional views of the structure shown in FIGS. 15A and 15B. FIGS. 24A and 24B show the structure after deposition of the ESL 122, similar to the structure shown in FIG. 22.

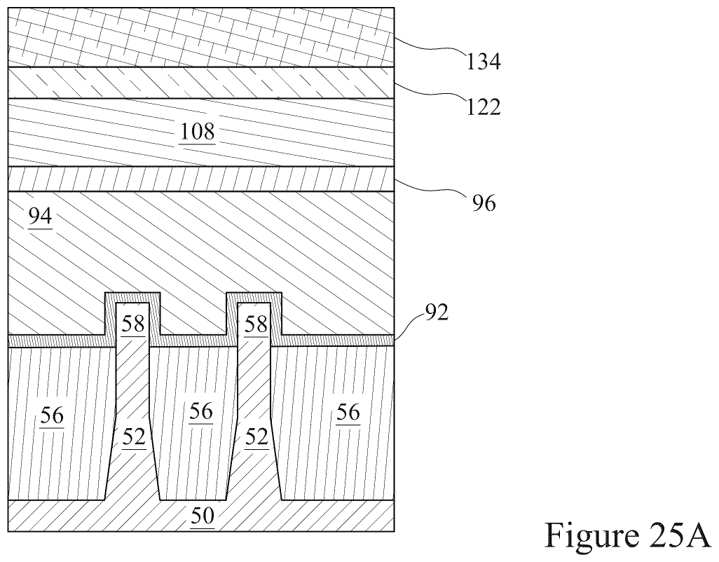

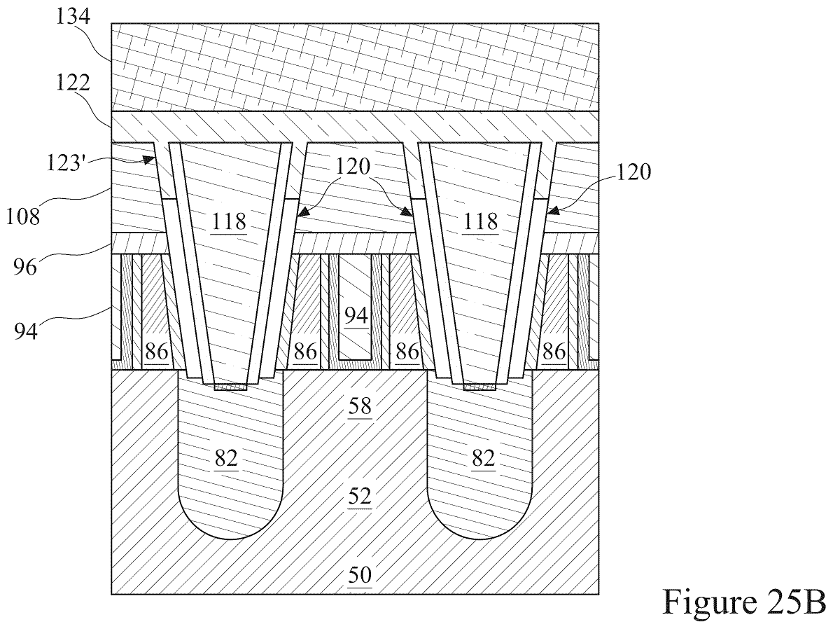

Turning to FIGS. 25A and 25B, a dielectric layer 134 may be formed over the ESL 122, in accordance with some embodiments. The dielectric layer 134 may be formed from a suitable dielectric material such as a low-k dielectric material, a polymer such as a polyimide, a silicon oxide, a silicon nitride, silicon carbide, silicon carbonitride, silicon oxycarbonitride, the like, or a combination thereof. The dielectric layer 134 may be formed using a suitable process such as spin-on coating, CVD, PVD, ALD, or the like. In some embodiments, the dielectric layer 134 may be formed in a manner similar to the first ILD 88 or the second ILD 108 as described previously.

In FIGS. 26A and 26B, openings 138 and recesses 139 may be formed, in accordance with some embodiments. The openings 138 extend through the dielectric layer 134 and the ESL 122 to expose the source/drain contacts 118. FIG. 26B shows an embodiment in which a single opening 138 exposes two adjacent source/drain contacts 118, but in other embodiments a single opening 138 may expose a single source/drain contact 118 or more than two source/drain contacts 118. The openings 138 and recesses 139 may be formed using suitable photolithography and etching techniques. For example, a photoresist (e.g., a single layer or multi-layer photoresist structure) may be formed over the dielectric layer 134. The photoresist may then be patterned to expose the dielectric layer 134 in regions corresponding to the openings 138. One or more suitable etching processes may then be performed to etch the openings 138, using the patterned photoresist as an etching mask. The one or more etching processes may include wet etching processes and/or dry etching processes. In some embodiments, the ESL 122 may be used as an etch stop layer when forming the openings 138. The openings 138 may have tapered sidewalls as shown in FIG. 26B or may have sidewalls having a different profile (e.g., vertical sidewalls).

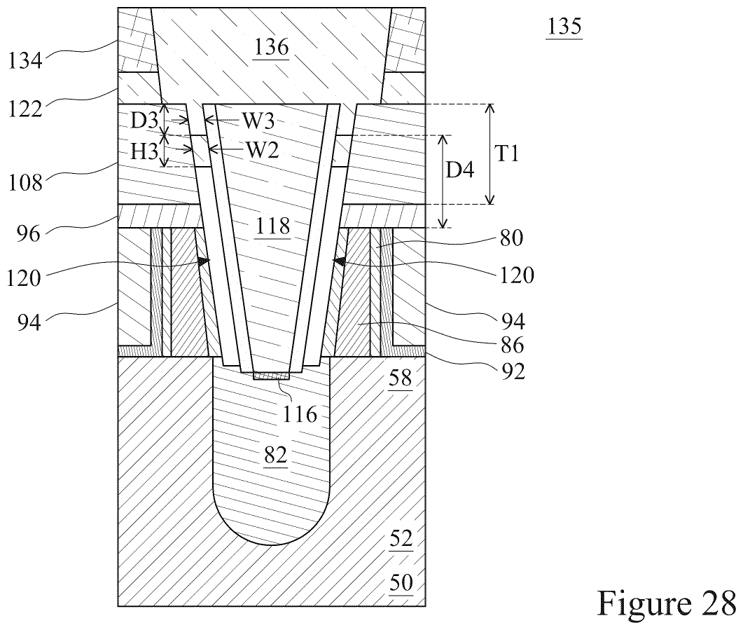

Still referring to FIG. 26B, portions of the sealing regions 123′ may also be removed by the etching process(es), forming recesses 139 that extend into the initial air gaps 120′ (see FIG. 21). The etching process(es) may be controlled such that the air gaps 120 are still sealed by remaining portions of the sealing regions 123′ after forming the openings 138. The remaining portions of the sealing regions 123′ may be referred to as “seals 123.” The use of the sealing regions 123′ to seal the air gaps 120 may prevent the air gaps 120 from being exposed when the openings 138 are formed, due to the remaining portions of the sealing regions 123′ that form seals 123. In some embodiments, the recesses 139 may extend a vertical distance D2 into the initial air gaps 120′ that is between about 0 nm and about 15 nm, though other distances are possible. Possible dimensions of the seals 123 are described below in greater detail for FIG. 28.

Additionally, the presence of the seals 123 protects the air gaps 120 and blocks subsequently formed conductive material from entering the air gaps 120, which can reduce the chance of leakage between subsequently-formed conductive features 136 (see FIG. 27B) and the gate stack 92/94. For example, while FIG. 26B shows the openings 138 patterned to extend over the air gaps 120, in other cases, the openings 138 may be undesirably formed extending over the air gaps 120 due to e.g. photolithographic misalignment. As such, subsequently deposited material is prevented from entering the air gaps 120 by the seals 123. By controlling the depth D2 of the recesses 139 in relation to the vertical distance D1 (see FIG. 22) of the sealing regions 123′, the location and size of the seals 123 can be controlled, which may depend on a particular application or desired structure. For example, seals 123 that have a larger size may provide more protection from leakage, or seals 123 that have a smaller size may allow for larger air gaps 120 and thus further reduce parasitic capacitance. These are examples, and other configurations or considerations are possible.

In FIGS. 27A and 27B, conductive features 136 are formed to contact the source/drain contacts 118, in accordance with some embodiments. FIG. 28 illustrates a detailed view of region 135 of FIG. 27B. The conductive features 136 may include one or more metal lines and/or vias that make physical and electrical contact with the source/drain contacts 118. The conductive features 136 may be, for example, redistribution layers. The conductive features 136 may be formed using any suitable technique.

In some embodiments, the material of the conductive features 136 may be formed using a single and/or a dual damascene process, a via-first process, or a metal-first process. In some embodiments, a liner 137 (shown in FIG. 28), such as a diffusion barrier layer, an adhesion layer, or the like, is formed in the openings 138 and in the recesses 139. The liner may include titanium, titanium nitride, tantalum, tantalum nitride, or the like, which may be formed using a deposition process such as CVD, ALD, or the like. A conductive material may then be formed over the liner 137. The conductive material may be copper, a copper alloy, silver, gold, tungsten, cobalt, aluminum, nickel, the like, or a combination thereof. The conductive material may be formed over the liner 137 in the openings 138 and recesses 139 by, for example, an electro-chemical plating process, CVD, ALD, PVD, the like, or a combination thereof. The material of the liner 137 and/or the conductive material is blocked from entering the air gaps 120 by the seals 123. A planarization process, such as a CMP, may be performed to remove excess material from a surface of the dielectric layer 134. The remaining liner 137 and conductive material form the conductive features 136. The conductive features 136 may be formed using other techniques in other embodiments. A seal 123 may be separated from a remaining portion of the ESL 122 (e.g., a portion on the second ILD 108) by a conductive feature 136, as shown in FIG. 28.

FIG. 27A also shows a gate contact 132 that is physically and electrically coupled to the gate electrode 94. The gate contacts 132 may be formed, for example, by forming an opening that exposes the gate electrode 94 using suitable photolithography and etching processes and then depositing an optional liner and a conductive material within the opening. The gate contacts 132 may be formed before or after the formation of the dielectric layer 134. The source/drain contacts 118 and gate contacts 132 may be formed in different processes, or may be formed in the same process. In some embodiments, some conductive features 136 may also be formed that contact the gate contacts 132 (not shown in FIG. 27A).

Referring to FIG. 28, each seal 123 may be formed having a width that is about the same as the width W2 of the initial air gap 120′, described previously. The width of the seals 123 may be substantially constant, or the seals 123 may have sidewall profiles that are concave, convex, tapered, or irregular. The seals 123 may have substantially vertical sidewalls or may have at least partially angled sidewalls, as shown in FIG. 28. In some embodiments, the seals 123 may extend a vertical height H3 that is between about 1 nm and about 15 nm, though other heights are possible. In some embodiments, the height H3 of the seals 123 may be between about 1% and about 150% of the thickness T1 of the second ILD 108, though other fractions are possible. In some cases, a larger height H3 may provide improved sealing of the air gaps 120 and improved protection from electrical shorts or leakage. In some embodiments, the top surfaces of the seals 123 may be a vertical distance D4 above the gate stack (e.g., is over the gate dielectric layer 92 and gate electrode 94) that is between about 0 nm and about 35 nm, though other distances are possible. The top surfaces of the seals 123 may be above the gate stack, below the gate stack, or about level with the gate stack. In some cases, a larger vertical distance D4 between the top surfaces of the seals 123 and the gate stack may allow for improved protection from leakage or shorts between the conductive features 136 and the gate stacks. In some embodiments, the seals 123 may have an aspect ratio (width:height) that is between about 4:1 and about 1:30, though other aspect ratios are possible. In some cases, seals 123 having a relatively wider aspect ratio may allow for larger air gaps 120, which can improve capacitance reduction. In some embodiments, the seals 123 may have substantially flat top surfaces and/or substantially flat bottom surfaces, which may be substantially horizontal (e.g., parallel to the plane of the substrate 50) or which may be angled with respect to the horizontal. FIG. 28 illustrates an embodiment in which the top surfaces and bottom surfaces of the seals 123 are substantially flat and substantially horizontal. In other embodiments, the top surfaces and/or the bottom surfaces of the seals 123 may be convex, concave, round, irregular, or have another shape.

Referring to FIG. 28, portions of the conductive features 136 that fill the recesses 139 may have a width W3 that is between about 0.5 nm and about 4 nm, although other widths are possible. The width W3 may be about the same as the width W2 of the initial air gap 120′, described previously. The width of the conductive features 136 within the recesses 139 may be substantially constant, or may have a sidewall profiles that are concave, convex, tapered, or irregular. The conductive features 136 within the recesses 139 may have substantially vertical sidewalls or may have at least partially angled sidewalls, as shown in FIG. 28. In some embodiments, the conductive features 136 within the recesses 139 may extend below a top surface of the second ILD 108 a vertical distance D3 that is between about 0 nm and about 15 nm, though other distances are possible. The vertical distance D3 may be about the same as the vertical distance D2 of the recesses 139 described for FIG. 26B. In some embodiments, the vertical distance D3 may be between about 0% and about 150% of the thickness T1 of the second ILD 108, though other fractions are possible. In some cases, a smaller vertical distance D3 may allow for the formation of larger air gaps 120, and thus may allow for improved capacitance reduction. In some embodiments, the conductive features 136 within the recesses 139 may have an aspect ratio (width:height) that is between about 10:1 and about 1:30, though other aspect ratios are possible. In some cases, a relatively wider aspect ratio may allow for larger air gaps 120, which can improve capacitance reduction. In some embodiments, conductive features 136 within the recesses 139 may have substantially flat bottom surfaces, which may be substantially horizontal (e.g., parallel to the plane of the substrate 50) or which may be angled with respect to the horizontal. FIG. 28 illustrates an embodiment in which the bottom surfaces of the conductive features 136 within the recesses 139 are substantially flat and substantially horizontal. In other embodiments, the bottom surfaces of the conductive features 136 within the recesses 139 may be convex, concave, round, irregular, or have another shape.

Embodiments may achieve advantages. By forming air gaps between the source/drain contacts and the gate stack of a FinFET device, capacitance between the source/drain contacts and the gate stack may be reduced. Reducing this capacitance can improve the speed or high-frequency operation of the FinFET device. Additionally, the top of the air gaps are sealed by remaining portions of an overlying dielectric layer, which may be an etch stop layer. By sealing the air gaps, unwanted material can be blocked from entering the air gaps and degrading device performance or causing process defects. For example, the sealing portions of the dielectric layer can improve isolation between a source/drain contact and a gate of a FinFET. In some cases, controlling the dose of an ALD process and/or the RF time of a PEALD process used to form the dielectric layer can control the size or depth of the remaining portions of the dielectric layer within the air gaps.

In some embodiments, a device includes a fin extending from a semiconductor substrate; a gate stack over the fin; a spacer on a sidewall of the gate stack; a source/drain region in the fin adjacent the spacer; an inter-layer dielectric layer (ILD) extending over the gate stack, the spacer, and the source/drain region; a contact plug extending through the ILD and contacting the source/drain region; a dielectric layer including a first portion on a top surface of the ILD and a second portion extending between the ILD and the contact plug, wherein a top surface of the second portion is closer to the substrate than the top surface of the ILD; and an air gap between the spacer and the contact plug, wherein the second portion of the dielectric layer seals the top of the air gap. In an embodiment, the device includes a conductive material extending on the ILD, the second portion, and the contact plug. In an embodiment, the conductive material is separated from the air gap by the second portion. In an embodiment, the first portion is separated from the second portion by the conductive material. In an embodiment, the dielectric layer includes silicon nitride. In an embodiment, the top surface of the second portion is in the range between 0 nm and 15 nm below the top surface of the ILD. In an embodiment, the second portion has a vertical thickness in the range between 1 nm and 15 nm. In an embodiment, the second portion has a width in the range between 0.5 nm and 4 nm. In an embodiment, the first portion has a vertical thickness in the range between 3 nm and 30 nm. In an embodiment, a bottom surface of the second portion is farther from the substrate than a bottom surface of the ILD.

In some embodiments, a method includes forming a fin protruding from a substrate; forming a gate structure over a channel region of the fin; forming a gate spacer along a sidewall of the gate structure; forming an epitaxial region in the fin adjacent the channel region; depositing a first dielectric layer over the gate structure and the gate spacer, the first dielectric layer including a first dielectric material; forming a contact plug extending through the first dielectric layer and contacting the epitaxial region, wherein an air gap separates the contact plug and the gate spacer; depositing a second dielectric layer over the first dielectric layer and over the contact plug, including sealing a lower region of the air gap with the second dielectric layer, wherein the second dielectric layer includes a second dielectric material different from the first dielectric material; etching the second dielectric layer to expose the contact plug, wherein after etching the second dielectric layer a remaining portion of the second dielectric layer seals the lower region of the air gap; and depositing a conductive material on the contact plug, including depositing the conductive material between the contact plug and the first dielectric material and on the remaining portion of the second dielectric layer. In an embodiment, an upper region of the air gap separates the first dielectric layer and the contact plug. In an embodiment, a thickness of the remaining portion of the second dielectric layer is less than a thickness of the first dielectric layer. In an embodiment, the remaining portion of the second dielectric layer is closer to the substrate than a top surface of the first dielectric layer. In an embodiment, the depositing of the conductive material includes depositing the conductive material on a top surface of the first dielectric layer. In an embodiment, the remaining portion of the second dielectric layer extends from the first dielectric layer to a spacer layer on the contact plug.

In some embodiments, a method includes forming a gate stack over a semiconductor fin; forming an epitaxial source/drain region in the semiconductor fin adjacent the gate stack; depositing a first dielectric layer over the gate stack and over the epitaxial source/drain region; forming an opening in the first dielectric layer to expose the epitaxial source/drain region; depositing a sacrificial material within the opening; depositing a first conductive material over the sacrificial material within the opening; removing the sacrificial material to form a gap; depositing a second dielectric layer over the first dielectric layer, over the conductive material, and over the gap, wherein the second dielectric layer extends a first distance into the gap; and etching the second dielectric layer to expose the first conductive material, wherein first portions of the second dielectric layer remain within the gap after the etching. In an embodiment, the depositing of the second dielectric layer includes depositing silicon nitride using a plasma-enhanced atomic layer deposition (PEALD) process. In an embodiment, the etching of the second dielectric layer includes etching second portions of the second dielectric layer within the gap. In an embodiment, the method includes depositing a second conductive material on the first conductive material and on the first portions of the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a source/drain region in a semiconductor fin;
forming a gate structure on the semiconductor fin;
forming a first insulating layer on the gate structure;
forming a conductive feature on the source/drain region, wherein the conductive feature is laterally separated from the gate structure and the first insulating layer by an air gap;
forming a seal region between the first insulating layer and the conductive feature, wherein the seal region seals the air gap, wherein a top surface of the seal region is lower than a top surface of the first insulating layer; and
forming a conductive layer covering a top surface of the seal region and a top surface of the conductive feature.

2. The method of claim 1, wherein forming the seal region comprises:
forming a second insulating layer over the first insulating layer, the air gap, and the conductive feature; and
performing an etching process on the second insulating layer.

3. The method of claim 1, wherein a bottom surface of the seal region is higher than a bottom surface of the first insulating layer.

4. The method of claim 1, wherein the air gap exposes a top surface of the source/drain region.

5. The method of claim 1, wherein top surfaces of the conductive feature and the first insulating layer are level.

6. The method of claim 1, wherein the conductive layer extends on a sidewall of the first insulating layer.

7. The method of claim 1 further comprising forming a second insulating layer on a sidewall of the conductive feature, wherein the air gap extends along the second insulating layer.

8. The method of claim 1, wherein the seal region and the first insulating layer are different materials.

9. A method comprising:
forming a gate stack over a semiconductor fin;
forming an epitaxial region in the semiconductor fin and adjacent the gate stack;
depositing a sacrificial layer over the gate stack and on the epitaxial region;
depositing a first conductive material over the sacrificial layer and on the epitaxial region;
etching the sacrificial layer to form an air gap between the first conductive material and the gate stack, wherein the air gap has a first vertical height;
depositing a dielectric material over the gate stack, over the first conductive material, and within the air gap, wherein after the depositing the dielectric material the air gap has a second vertical height that is less than the first vertical height;
etching the dielectric material to expose the first conductive material and remove an upper portion of the dielectric material within the air gap, wherein after the etching the dielectric material the air gap has the second vertical height; and
depositing a second conductive material on the first conductive material and on the portion of the dielectric material within the air gap.

10. The method of claim 9, wherein the second conductive material extends within the air gap lower than a top surface of the first conductive material.

11. The method of claim 9, wherein after etching the dielectric material, the portion of the dielectric material within the air gap is discontinuous with dielectric material remaining over the gate stack.

12. The method of claim 9 further comprising depositing an interlayer dielectric (ILD) layer over the gate stack, wherein the second conductive material is deposited on a top surface of the ILD layer.

13. The method of claim 9 further comprising depositing a spacer layer on the sacrificial layer before depositing the first conductive material.

14. The method of claim 9, wherein the portion of the dielectric material within the air gap is higher than the gate stack.

15. The method of claim 9 further comprising, before depositing the first conductive material, etching the sacrificial layer to expose the epitaxial region.

16. A method comprising:
forming a gate spacer on a fin;
forming a source/drain region in the fin adjacent the gate spacer;
forming a first dielectric layer over the gate spacer;
forming a sacrificial layer extending on sidewalls of the gate spacer and first dielectric layer;
forming a contact spacer layer extending on a sidewall of the sacrificial layer;
forming a first conductive layer extending on a sidewall of the contact spacer layer;
removing the sacrificial layer to form a gap between the contact spacer layer and the first dielectric layer, and between the contact spacer layer and the gate spacer;
forming an etch stop layer over the first dielectric layer;
etching the etch stop layer to form a seal between the contact spacer layer and the first dielectric layer that seals the gap, and
forming a second conductive layer on the seal and on the first conductive layer.

17. The method of claim 16, wherein the sacrificial layer contacts the source/drain region.

18. The method of claim 16, wherein the contact spacer layer contacts the source/drain region.

19. The method of claim 16, wherein the seal has a thickness that is less than a thickness of the first dielectric layer.

20. The method of claim 16, wherein the sacrificial layer is silicon.
